(19) United States
(12) Patent Application Publication
(10) Pub. No.: US 2026/0074661 A1
(43) Pub. Date: Mar. 12, 2026

(54) RADIO FREQUENCY MODULE

(71) Applicant: Murata Manufacturing Co., Ltd., Nagaokakyo-shi (JP)

(72) Inventor: Shogo YANASE, Nagaokakyo-shi (JP)

(73) Assignee: Murata Manufacturing Co., Ltd., Nagaokakyo-shi (JP)

(21) Appl. No.: 19/307,064

(22) Filed: Aug. 22, 2025

(30) Foreign Application Priority Data
Sep. 10, 2024 (JP) 2024-156548

(51) Int. Cl. H03F 3/24; H01L 25/18; H04B 1/04

(52) U.S. Cl. CPC H03F 3/245; H04B 1/04; H03F 2200/171; H03F 2200/451; H04B 2001/0408; H10W 90/00

(57) ABSTRACT

A radio frequency module includes a module laminate, first to third substrates disposed on the module laminate, and first and second power amplifier circuits. Each power amplifier circuit includes a preceding-stage amplifier, a subsequent-stage amplifier, and a passive component. The passive component is connected between the preceding-stage amplifier and the subsequent-stage amplifier. The preceding-stage amplifiers of the first and second power amplifiers are included in the first semiconductor component. The subsequent-stage amplifier of the first power amplifier circuit is included in the second semiconductor component. The subsequent-stage amplifier of the second power amplifier circuit is included in the third semiconductor component. The first semiconductor component is disposed between the passive components of the first and second power amplifier circuits in a plan view of the module laminate.

### CROSS-REFERENCE TO RELATED APPLICATION

The present application claims priority to Japanese patent application JP2024-156548, filed Sep. 10, 2024, the entire contents of which being incorporated herein by reference.

### BACKGROUND

### 1. Field

The present disclosure relates to a radio frequency module.

### 2. Description of the Related Art

In mobile communication apparatuses such as mobile phones, due to particular advances in multiband capabilities, the layout and configuration of circuit elements in radio frequency front-end circuits have become increasingly complex. Japanese Unexamined Patent Application Publication No. 2021-175073 discloses a radio frequency module including a differential amplifier circuit that amplifies transmission signals of Bands A and B, and a differential amplifier circuit that amplifies a transmission signal of Band C.

### SUMMARY

However, with the technique according to the related art mentioned above, coupling between two interstage transformers included in the two differential amplifier circuits may cause degradation of the isolation between the two amplifier circuits. Accordingly, the present disclosure provides a radio frequency module capable of reducing degradation of the isolation between two amplifier circuits.

A radio frequency module according to an aspect of the present disclosure includes a module laminate, and a first power amplifier circuit and a second power amplifier circuit. The module laminate has a first major face and a second major face that are opposite to each other. The first power amplifier circuit and the second power amplifier circuit are disposed at the module laminate. The first power amplifier circuit includes a first preceding-stage amplifier, two first subsequent-stage amplifiers, and a first balun connected between: the first preceding-stage amplifier; and the two first subsequent-stage amplifiers. The second power amplifier circuit includes a second preceding-stage amplifier, two second subsequent-stage amplifiers, and a second balun connected between: the second preceding-stage amplifier; and the two second subsequent-stage amplifiers. The first preceding-stage amplifier and the second preceding-stage amplifier are included in a first semiconductor component disposed at the module laminate. The two first subsequent-stage amplifiers are included in a second semiconductor component disposed at the module laminate. The two second subsequent-stage amplifiers are included in a third semiconductor component disposed at the module laminate. The first semiconductor component is disposed between the first balun and the second balun in plan view of the module laminate.

A radio frequency module according to an aspect of the present disclosure includes a module laminate, and a first power amplifier circuit and a second power amplifier circuit that are disposed at the module laminate. The first power amplifier circuit includes a first preceding-stage amplifier, a first subsequent-stage amplifier, and a first inductor connected between: a path that connects the first preceding-stage amplifier and the first subsequent-stage amplifier to each other; and ground. The second power amplifier circuit includes a second preceding-stage amplifier, a second subsequent-stage amplifier, and a second inductor connected between: a path that connects the second preceding-stage amplifier and the second subsequent-stage amplifier to each other; and ground. The first preceding-stage amplifier and the second preceding-stage amplifier are included in a first semiconductor component disposed at the module laminate. The first subsequent-stage amplifier is included in a second semiconductor component disposed at the module laminate. The second subsequent-stage amplifier is included in a third semiconductor component disposed at the module laminate. The first semiconductor component is disposed between the first inductor and the second inductor in plan view of the module laminate.

The present disclosure makes it possible to reduce degradation of the isolation between two amplifier circuits.

### BRIEF DESCRIPTION OF THE DRAWINGS

FIG. 1 illustrates the configuration of a communication device according to Embodiment 1;

FIG. 2 is a circuit diagram of a radio frequency module according to Embodiment 1;

FIG. 3 is a plan view of the radio frequency module according to Embodiment 1;

FIG. 4 is a plan view of the radio frequency module according to Embodiment 1;

FIG. 5 is a partial cross-sectional view of the radio frequency module according to Embodiment 1;

FIG. 6 is a partial cross-sectional view of the radio frequency module according to Modification 1 of Embodiment 1;

FIG. 7 is a partial cross-sectional view of the radio frequency module according to Modification 2 of Embodiment 1;

FIG. 8 is a plan view of the radio frequency module according to Modification 3 of Embodiment 1;

FIG. 9 is a plan view of the radio frequency module according to Modification 4 of Embodiment 1;

FIG. 10 is a plan view of the radio frequency module according to Modification 4 of Embodiment 1;

FIG. 11 is a circuit diagram of a radio frequency module according to Embodiment 2; and

FIG. 12 is a plan view of the radio frequency module according to Embodiment 2.

### DETAILED DESCRIPTION

Embodiments of the present disclosure will now be described in detail with reference to the drawings. Embodiments described below all represent generic or specific examples. Features presented in the following embodiments, such as numerical values, shapes, materials, constituent elements, and the positioning and connection of constituent elements, are illustrative only and not intended to be limiting of the present disclosure.

The drawings are schematic in nature with emphases, omissions, or proportion adjustments made as necessary to illustrate the present disclosure, and do not necessarily represent exact details. Accordingly, the illustrated shapes, positional relationships, and proportions may differ from the actuality. Throughout the drawings, identical reference signs are used to designate substantially identical features, and repetitive description will be sometimes omitted or simplified.

In the drawings described below, an x-axis and a y-axis are axes that are orthogonal to each other in a plane parallel to a major face of a module laminate. A z-axis is an axis perpendicular to the major face of the module laminate. The z-axis has a positive direction defined as an upward direction, and a negative direction defined as a downward direction.

As used in the following description, expressions such as “connected” mean not only that circuit elements are directly connected by a connection terminal and/or a wiring conductor, but also that circuit elements are electrically connected with another circuit element interposed therebetween. Expressions such as “C is connected between A and B” mean that C is connected at one end to A and connected at the other end to B, and mean that C is connected in series with a path that connects A and B to each other. Expressions such as “path that connects A and B to each other” mean a path formed by a conductor that electrically connects A to B.

Expressions such as “passband of a filter” refer to a portion of the frequency spectrum transmitted by the filter, which is defined as a frequency band in which the output power is not attenuated by 3 dB or more relative to the maximum output power. Therefore, the passband of a band pass filter is defined as a range of frequencies between two points at which the output power is attenuated by 3 dB relative to the maximum output power.

Expressions such as “transmission band” mean a frequency band used for transmission in a communication device. Expressions such as “reception band” mean a frequency band used for reception in the communication device. For example, in a frequency division duplex (FDD) band, different frequency bands (uplink band and downlink band) are used as a transmission band and a reception band. Further, for example, in a time division duplex (TDD) band, the same frequency band is used as a transmission band and a reception band.

Expressions such as “harmonic bands of a predetermined band” mean bands ranging from n times the lower end of the predetermined band to n times the upper end of the predetermined band. In this case, “n” is a natural number greater than or equal to 2. For example, a second-order harmonic band of a predetermined band refers to a band ranging from twice the lower end of the predetermined band to twice the upper end of the predetermined band, and a third-order harmonic band of the predetermined band refers to a band ranging from three times the lower end of the predetermined band to three times the upper end of the predetermined band. When no order is specified, expressions such as “harmonic bands” mean harmonic bands of all orders.

Expressions such as “terminal” mean a point where a conductor within an element terminates. When the impedance of a conductor located between elements is sufficiently low, a terminal is interpreted not only as a single point, but also as any given point on the conductor located between the elements or as the entire conductor.

Expressions such as “a component is disposed at a laminate (substrate/board)” include that the component is disposed on a major face of the laminate, and that the component is disposed in the laminate. Expressions such as “a component is disposed on a major face of a laminate” include not only that the component is disposed in contact with the major face of the laminate, but also that the component is disposed above the major face without making contact with the major face (e.g., the component is stacked on another component disposed in contact with the major face). The expressions such as “a component is disposed on a major face of a laminate” may also include that the component is disposed at a recess defined in the major face. Expressions such as “a component is disposed in a laminate” include, in addition to the meaning that the component is encapsulated in the laminate, the following meanings: the entirety of the component is disposed between opposite major faces of the laminate but part of the component is not covered by the laminate; and only part of the component is disposed in the laminate.

Expressions such as “A is connected between B and C” mean that at least one of line segments connecting a given point in B and a given point in C passes through A. Expressions such as “A is disposed closer to C than is B” mean that the distance between A and C is less than the distance between B and C. In this regard, expressions such as “the distance between A (B) and C” mean the length of the shortest one of line segments (i.e., the shortest distance) connecting a given point on the surface of A (B) and a given point on the surface of C.

Expressions such as “plan view of a module laminate” mean a view of an object orthogonally projected onto an xy-plane in the negative direction of the z-axis. Expressions such as “A overlaps B in plan view of a module laminate” mean that the region of A orthogonally projected onto an xy-plane overlaps the region of B orthogonally projected onto the xy-plane.

Expressions such as “A is disposed adjacent to an edge of B in plan view of a module laminate” indicate that, when projected onto an xy-plane, A and the edge of B are positioned in proximity to each other. Specifically, such expressions mean that neither another circuit component nor another edge of B exists in a space where A faces the edge of B. In other words, the expressions such as “A is disposed adjacent to an edge of B in plan view of a module laminate” mean that none of a plurality of line segments each extending from a given point on a boundary line where A faces the edge of B to the edge of B in the direction normal to the boundary line passes through a circuit component other than A and B and through another edge of B. Accordingly, it is permitted that A overlaps the edge of B in the xy-plane. In this regard, a circuit component means a component including an active element and/or a passive element. That is, examples of such circuit components include active components such as transistors or diodes, and passive components such as inductors, transformers, capacitors, or resistors, but do not include electromechanical components such as terminals, connectors, or wiring.

Further, “parallel”, “perpendicular”, or other such expressions indicative of the relationship between elements, and “straight line” or other such expressions indicative of a shape of an element, as well as numerical ranges are not intended to represent only their strict meanings but are meant to also include their substantial equivalents with a margin of error of, for example, about several percent.

### Embodiment 1

Embodiment 1 will now be described.

### 1.1. Configuration of Communication Device

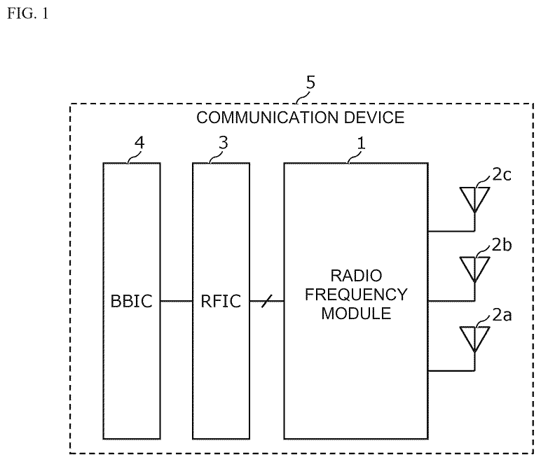

First, the configuration of a communication device 5 according to Embodiment 1 will be described with reference to FIG. 1. FIG. 1 illustrates the configuration of the communication device 5 according to Embodiment 1.

FIG. 1 illustrates an exemplary configuration. The communication device 5 may be implemented by using any one of a wide variety of circuit implementations and circuit technologies. Accordingly, the description of the communication device 5 provided below is not to be construed restrictively.

The communication device 5 may be used to provide wireless communication. In one example, the communication device 5 may be incorporated into UE in a cellular network (also referred to as mobile network), such as mobile phones, smartphones, tablet computers, or wearable devices. In another example, the incorporation of the communication device 5 makes it possible to provide wireless communication to Internet of Things (IoT) sensor devices, medical/healthcare devices, vehicles, unmanned aerial vehicles (UAVs) (so-called drones), or automated guided vehicles (AGVs). In still another example, the incorporation of the communication device 5 makes it possible to provide wireless communication via wireless access points or wireless hotspots.

The communication device 5 includes a radio frequency module 1, antennas 2a, 2b, and 2c, a radio frequency integrated circuit (RFIC) 3, and a baseband integrated circuit (BBIC) 4.

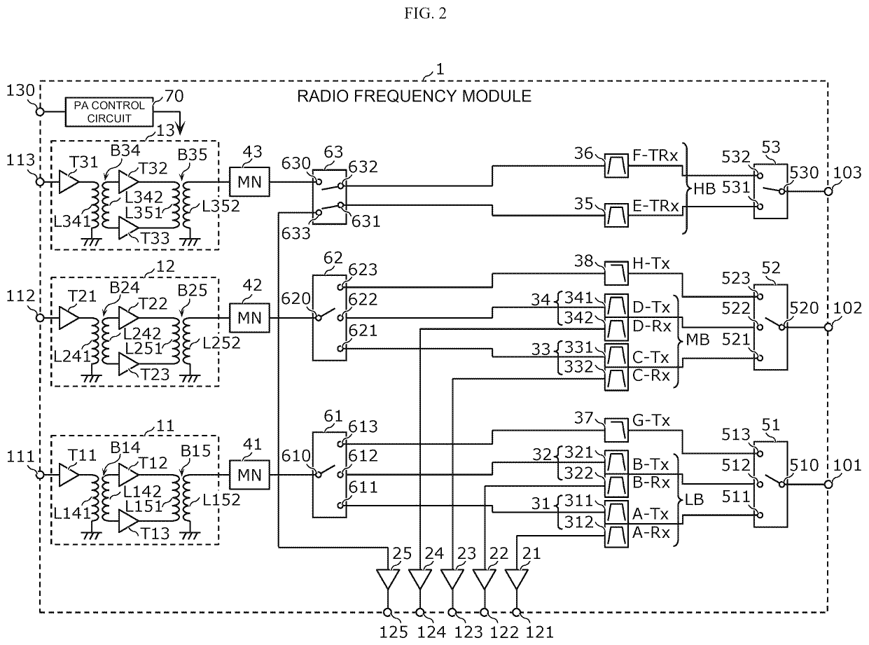

The radio frequency module 1 allows radio frequency signals to be transmitted between: the antennas 2a to 2c; and the RFIC 3. The circuit configuration of the radio frequency module 1 will be described later with reference to FIG. 2.

The antennas 2a to 2c are connected to the radio frequency module 1. The antennas 2a to 2c are capable of receiving a radio frequency signal from the radio frequency module 1 and transmitting the radio frequency signal to a location outside of the communication device 5. Further, the antennas 2a to 2c are capable of receiving a radio frequency signal from a location outside of the communication device 5 and supplying the radio frequency signal to the radio frequency module 1. A subset or all of the antennas 2a to 2c need not necessarily be included in the communication device 5. The communication device 5 may include one or more other antennas in addition to the antennas 2a to 2c.

The RFIC 3 is an example of a signal processing circuit that processes a radio frequency signal. Specifically, the RFIC 3 is capable of applying signal processing such as up-conversion to a transmission signal input from the BBIC 4, and outputting a radio frequency signal generated through the signal processing to the radio frequency module 1. Further, the RFIC 3 is also capable of applying signal processing such as down-conversion to a radio frequency reception signal input via the radio frequency module 1, and outputting a reception signal generated through the signal processing to the BBIC 4. The RFIC 3 may include a controller that controls switches, amplifiers, and other components included in the radio frequency module 1. The functionality of the RFIC 3 as a controller may be included in a component external to the RFIC 3, for example, in the BBIC 4 or in the radio frequency module 1.

The BBIC 4 is a baseband signal processing circuit that performs signal processing by using a band of frequencies lower than those of radio frequency signals to be transmitted by the radio frequency module 1. Examples of signals to be processed by the BBIC 4 include an image signal for image display, and/or an audio signal for telephone conversation via a speaker. The BBIC 4 need not necessarily be included in the communication device 5.

### 1.2. Circuit Configuration of Radio Frequency Module 1

The circuit configuration of the radio frequency module 1 according to Embodiment 1 will now be described with reference to FIG. 2. FIG. 2 is a circuit diagram of the radio frequency module 1 according to Embodiment 1.

FIG. 2 illustrates an exemplary circuit configuration. The radio frequency module 1 may be implemented by using any one of a wide variety of circuit implementations and circuit technologies. Accordingly, the description of the radio frequency module 1 provided below is not to be construed restrictively.

The radio frequency module 1 includes power amplifier circuits 11, 12, and 13, low-noise amplifier circuits 21, 22, 23, 24, and 25, duplexers 31, 32, 33, and 34, transmit/receive filters 35 and 36, transmit filters 37 and 38, matching circuits 41, 42, and 43, switch circuits 51, 52, 53, 61, 62, and 63, antenna connection terminals 101, 102, and 103, radio frequency input terminals 111, 112, and 113, radio frequency output terminals 121, 122, 123, 124, and 125, and a digital control terminal 130.

The antenna connection terminals 101 to 103 are external connection terminals of the radio frequency module 1. The antenna connection terminals 101 to 103 are respectively connected at locations outside the radio frequency module 1 to the antennas 2a to 2c, and respectively connected at locations inside the radio frequency module 1 to the switch circuits 51 to 53.

The radio frequency input terminals 111 to 113 are external connection terminals of the radio frequency module 1 to receive radio frequency signals from the RFIC 3. The radio frequency input terminals 111 to 113 are connected at locations outside the radio frequency module 1 to the RFIC 3, and respectively connected at locations inside the radio frequency module 1 to the power amplifier circuits 11 to 13.

The radio frequency output terminals 121 to 125 are external connection terminals of the radio frequency module 1 to supply radio frequency signals to the RFIC 3. The radio frequency output terminals 121 to 125 are connected at locations outside the radio frequency module 1 to the RFIC 3, and respectively connected at locations inside the radio frequency module 1 to the low-noise amplifier circuits 21 to 25.

The digital control terminal 130 is an external connection terminal of the radio frequency module 1 to receive a digital control signal from the RFIC 3. The digital control terminal 130 is connected at a location outside the radio frequency module 1 to the RFIC 3, and connected at a location inside the radio frequency module 1 to a PA control circuit 70. According to Embodiment 1, a source-synchronous serial data signal is used as the digital control signal. Alternatively, a clock-embedded serial data signal may be used as the digital control signal.

The power amplifier circuit 11 is an example of a first power amplifier. The power amplifier circuit 11 is connected between the radio frequency input terminal 111 and the matching circuit 41. Specifically, the power amplifier circuit 11 includes an input terminal connected to the radio frequency input terminal 111, and an output terminal connected to the matching circuit 41. The power amplifier circuit 11 is capable of amplifying transmission signals of Bands A, B, and G by using power supplied from a power source (not illustrated).

According to Embodiment 1, the power amplifier circuit 11 is a multistage amplifier circuit, and is a differential amplifier circuit. The power amplifier circuit 11 includes a preceding-stage amplifier T11, subsequent-stage amplifiers T12 and T13, and baluns B14 and B15.

The preceding-stage amplifier T11 is an example of a first preceding-stage amplifier. The preceding-stage amplifier T11 is connected between the radio frequency input terminal 111 and the balun B14. Specifically, the preceding-stage amplifier T11 includes an input terminal connected to the radio frequency input terminal 111, and an output terminal connected to the balun B14.

The subsequent-stage amplifiers T12 and T13 are an example of two first subsequent-stage amplifiers. The subsequent-stage amplifiers T12 and T13 are a pair of power amplifiers connected in parallel. The subsequent-stage amplifiers T12 and T13 are connected between the balun B14 and the balun B15. Specifically, the subsequent-stage amplifiers T12 and T13 each include an input terminal connected to the balun B14, and an output terminal connected to the balun B15.

The balun B14 is an example of a first balun. The balun B14 includes a primary coil L141, and a secondary coil L142 capable of electromagnetic field coupling with the primary coil L141. The primary coil L141 is connected at one end to the output terminal of the preceding-stage amplifier T11, and connected at the other end to ground. The secondary coil L142 is connected at one end to the input terminal of the subsequent-stage amplifier T12, and connected at the other end to the input terminal of the subsequent-stage amplifier T13. The balun B14 is capable of converting an unbalanced signal (single-ended signal) amplified by the preceding-stage amplifier T11 into a balanced signal (differential signal), and supplying the balanced signal to each of the two subsequent-stage amplifiers T12 and T13.

The balun B15 is an example of a fourth balun. The balun B15 includes a primary coil L151, and a secondary coil L152 capable of electromagnetic field coupling with the primary coil L151. The primary coil L151 is connected at one end to the output terminal of the subsequent-stage amplifier T12, and connected at the other end to the output terminal of the subsequent-stage amplifier T13. The secondary coil L152 is connected at one end to the matching circuit 41, and connected at the other end to ground. The balun B15 is capable of converting a balanced signal amplified by each of the subsequent-stage amplifiers T12 and T13 into an unbalanced signal.

The power amplifier circuit 12 is an example of a second power amplifier circuit. The power amplifier circuit 12 is connected between the radio frequency input terminal 112 and the matching circuit 42. Specifically, the power amplifier circuit 12 includes an input terminal connected to the radio frequency input terminal 112, and an output terminal connected to the matching circuit 42. The power amplifier circuit 12 is capable of amplifying transmission signals of Bands C, D, and H by using power supplied from a power source (not illustrated).

According to Embodiment 1, the power amplifier circuit 12 is a multistage amplifier circuit, and is a differential amplifier circuit. The power amplifier circuit 12 includes a preceding-stage amplifier T21, subsequent-stage amplifiers T22 and T23, and baluns B24 and B25.

The preceding-stage amplifier T21 is an example of a second preceding-stage amplifier. The preceding-stage amplifier T21 is connected between the radio frequency input terminal 112 and the balun B24. Specifically, the preceding-stage amplifier T21 includes an input terminal connected to the radio frequency input terminal 112, and an output terminal connected to the balun B24.

The subsequent-stage amplifiers T22 and T23 are an example of two second subsequent-stage amplifiers. The subsequent-stage amplifiers T22 and T23 are a pair of power amplifiers connected in parallel. The subsequent-stage amplifiers T22 and T23 are connected between the balun B24 and the balun B25. Specifically, the subsequent-stage amplifiers T22 and T23 each include an input terminal connected to the balun B24, and an output terminal connected to the balun B25.

The balun B24 is an example of a second balun. The balun B24 includes a primary coil L241, and a secondary coil L242 capable of electromagnetic field coupling with the primary coil L241. The primary coil L241 is connected at one end to the output terminal of the preceding-stage amplifier T21, and connected at the other end to ground. The secondary coil L242 is connected at one end to the input terminal of the subsequent-stage amplifier T22, and connected at the other end to the input terminal of the subsequent-stage amplifier T23. The balun B24 is capable of converting an unbalanced signal amplified by the preceding-stage amplifier T21 into a balanced signal, and supplying the balanced signal to each of the two subsequent-stage amplifiers T22 and T23.

The balun B25 is an example of a fifth balun. The balun B25 includes a primary coil L251, and a secondary coil L252 capable of electromagnetic field coupling with the primary coil L251. The primary coil L251 is connected at one end to the output terminal of the subsequent-stage amplifier T22, and connected at the other end to the output terminal of the subsequent-stage amplifier T23. The secondary coil L252 is connected at one end to the matching circuit 42, and connected at the other end to ground. The balun B25 is capable of converting a balanced signal amplified by each of the subsequent-stage amplifiers T22 and T23 into an unbalanced signal.

The power amplifier circuit 13 is an example of a third power amplifier circuit. The power amplifier circuit 13 is connected between the radio frequency input terminal 113 and the matching circuit 43. Specifically, the power amplifier circuit 13 includes an input terminal connected to the radio frequency input terminal 113, and an output terminal connected to the matching circuit 43. The power amplifier circuit 13 is capable of amplifying transmission signals of Bands E and F by using power supplied from a power source (not illustrated). The power amplifier circuit 13 need not necessarily be included in the radio frequency module 1.

According to Embodiment 1, the power amplifier circuit 13 is a multistage amplifier circuit, and is a differential amplifier circuit. The power amplifier circuit 13 includes a preceding-stage amplifier T31, subsequent-stage amplifiers T32 and T33, and baluns B34 and B35.

The preceding-stage amplifier T31 is an example of a third preceding-stage amplifier. The preceding-stage amplifier T31 is connected between the radio frequency input terminal 113 and the balun B34. Specifically, the preceding-stage amplifier T31 includes an input terminal connected to the radio frequency input terminal 113, and an output terminal connected to the balun B34.

The subsequent-stage amplifiers T32 and T33 are an example of two third subsequent-stage amplifiers. The subsequent-stage amplifiers T32 and T33 are a pair of power amplifiers connected in parallel. The subsequent-stage amplifiers T32 and T33 are connected between the balun B34 and the balun B35. Specifically, the subsequent-stage amplifiers T32 and T33 each include an input terminal connected to the balun B34, and an output terminal connected to the balun B35.

The balun B34 is an example of a third balun. The balun B34 includes a primary coil L341, and a secondary coil L342 capable of electromagnetic field coupling with the primary coil L341. The primary coil L341 is connected at one end to the output terminal of the preceding-stage amplifier T31, and connected at the other end to ground. The secondary coil L342 is connected at one end to the input terminal of the subsequent-stage amplifier T32, and connected at the other end to the input terminal of the subsequent-stage amplifier T33. The balun B34 is capable of converting an unbalanced signal amplified by the preceding-stage amplifier T31 into a balanced signal, and supplying the balanced signal to each of the two subsequent-stage amplifiers T32 and T33.

The balun B35 is an example of a sixth balun. The balun B35 includes a primary coil L351, and a secondary coil L352 capable of electromagnetic field coupling with the primary coil L351. The primary coil L351 is connected at one end to the output terminal of the subsequent-stage amplifier T32, and connected at the other end to the output terminal of the subsequent-stage amplifier T33. The secondary coil L352 is connected at one end to the matching circuit 43, and connected at the other end to ground. The balun B35 is capable of converting a balanced signal amplified by each of the subsequent-stage amplifiers T32 and T33 into an unbalanced signal.

The low-noise amplifier circuit 21 is connected between the duplexer 31 and the radio frequency output terminal 121. Specifically, the low-noise amplifier circuit 21 includes an input terminal connected to the duplexer 31, and an output terminal connected to the radio frequency output terminal 121. The low-noise amplifier circuit 21 is capable of amplifying a reception signal of Band A by using power supplied from a power source (not illustrated).

The low-noise amplifier circuit 22 is connected between the duplexer 32 and the radio frequency output terminal 122. Specifically, the low-noise amplifier circuit 22 includes an input terminal connected to the duplexer 32, and an output terminal connected to the radio frequency output terminal 122. The low-noise amplifier circuit 22 is capable of amplifying a reception signal of Band B by using power supplied from a power source (not illustrated).

The low-noise amplifier circuit 23 is connected between the duplexer 33 and the radio frequency output terminal 123. Specifically, the low-noise amplifier circuit 23 includes an input terminal connected to the duplexer 33, and an output terminal connected to the radio frequency output terminal 123. The low-noise amplifier circuit 23 is capable of amplifying a reception signal of Band C by using power supplied from a power source (not illustrated).

The low-noise amplifier circuit 24 is connected between the duplexer 34 and the radio frequency output terminal 124. Specifically, the low-noise amplifier circuit 24 includes an input terminal connected to the duplexer 34, and an output terminal connected to the radio frequency output terminal 124. The low-noise amplifier circuit 24 is capable of amplifying a reception signal of Band D by using power supplied from a power source (not illustrated.

The low-noise amplifier circuit 25 is connected between the switch circuit 63 and the radio frequency output terminal 125. Specifically, the low-noise amplifier circuit 25 includes an input terminal connected to the switch circuit 63, and an output terminal connected to the radio frequency output terminal 125. The low-noise amplifier circuit 25 is capable of amplifying reception signals of Bands E and F by using power supplied from a power source (not illustrated).

The duplexer 31 is connected between: the antenna connection terminal 101; and the power amplifier circuit 11 and the low-noise amplifier circuit 21. The duplexer 31 includes a transmit filter 311 and a receive filter 312, and is capable of isolating a transmission signal of Band A and a reception signal of Band A from each other.

The transmit filter 311 is an example of a first transmit filter. The transmit filter 311 is a band pass filter having a passband that includes the transmission band of Band A (A-Tx). The transmit filter 311 is capable of passing signals within the transmission band of Band A, and attenuating signals outside the transmission band of Band A. The transmit filter 311 is connected at one end to a selection terminal 511 of the switch circuit 51, and connected at the other end to a selection terminal 611 of the switch circuit 61.

The receive filter 312 is a band pass filter having a passband that includes the reception band of Band A (A-Rx). The receive filter 312 is capable of passing signals within the reception band of Band A, and attenuating signals outside the reception band of Band A. The receive filter 312 is connected at one end to the selection terminal 511 of the switch circuit 51, and connected at the other end to the low-noise amplifier circuit 21. The receive filter 312 need not necessarily be included in the radio frequency module 1.

The duplexer 32 is connected between: the antenna connection terminal 101; and the power amplifier circuit 11 and the low-noise amplifier circuit 22. The duplexer 32 includes a transmit filter 321 and a receive filter 322, and is capable of isolating a transmission signal of Band B and a reception signal of Band B from each other. The duplexer 32 need not necessarily be included in the radio frequency module 1.

The transmit filter 321 is a band pass filter having a passband that includes the transmission band of Band B (B-Tx). The transmit filter 321 is capable of passing signals within the transmission band of Band B, and attenuating signals outside the transmission band of Band B. The transmit filter 321 is connected at one end to a selection terminal 512 of the switch circuit 51, and connected at the other end to a selection terminal 612 of the switch circuit 61.

The receive filter 322 is a band pass filter having a passband that includes the reception band of Band B (B-Rx). The receive filter 322 is capable of passing signals within the reception band of Band B, and attenuating signals outside the reception band of Band B. The receive filter 322 is connected at one end to the selection terminal 512 of the switch circuit 51, and connected at the other end to the low-noise amplifier circuit 22.

The duplexer 33 is connected between: the antenna connection terminal 102; and the power amplifier circuit 12 and the low-noise amplifier circuit 23. The duplexer 33 includes a transmit filter 331 and a receive filter 332, and is capable of isolating a transmission signal of Band C and a reception signal of Band C from each other.

The transmit filter 331 is an example of a second transmit filter. The transmit filter 331 is a band pass filter having a passband that includes the transmission band of Band C (C-Tx). The transmit filter 331 is capable of passing signals within the transmission band of Band C, and attenuating signals outside the transmission band of Band C. The transmit filter 331 is connected at one end to a selection terminal 521 of the switch circuit 52, and connected at the other end to a selection terminal 621 of the switch circuit 62.

The receive filter 332 is a band pass filter having a passband that includes the reception band of Band C (C-Rx). The receive filter 332 is capable of passing signals within the reception band of Band C, and attenuating signals outside the reception band of Band C. The receive filter 332 is connected at one end to the selection terminal 521 of the switch circuit 52, and connected at the other end to the low-noise amplifier circuit 23. The receive filter 332 need not necessarily be included in the radio frequency module 1.

The duplexer 34 is connected between: the antenna connection terminal 102; and the power amplifier circuit 12 and the low-noise amplifier circuit 24. The duplexer 34 includes a transmit filter 341 and a receive filter 342, and is capable of isolating a transmission signal of Band D and a reception signal of Band D from each other. The duplexer 34 need not necessarily be included in the radio frequency module 1.

The transmit filter 341 is a band pass filter having a passband that includes the transmission band of Band D (D-Tx). The transmit filter 341 is capable of passing signals within the transmission band of Band D, and attenuating signals outside the transmission band of Band D. The transmit filter 341 is connected at one end to a selection terminal 522 of the switch circuit 52, and connected at the other end to a selection terminal 622 of the switch circuit 62.

The receive filter 342 is a band pass filter having a passband that includes the reception band of Band D (D-Rx). The receive filter 342 is capable of passing signals within the reception band of Band D, and attenuating signals outside the reception band of Band D. The receive filter 342 is connected at one end to the selection terminal 522 of the switch circuit 52, and connected at the other end to the low-noise amplifier circuit 24. The receive filter 342 need not necessarily be included in the radio frequency module 1.

The transmit/receive filter 35 is an example of a third transmit filter. The transmit/receive filter 35 is connected between: the antenna connection terminal 103; and the power amplifier circuit 13 and the low-noise amplifier circuit 25. The transmit/receive filter 35 is a band pass filter having a passband that includes the transmission and reception bands of Band E (E-TRx). The transmit/receive filter 35 is capable of passing signals within the transmission and reception bands of Band E, and attenuating signals outside the transmission and reception bands of Band E. The transmit/receive filter 35 is connected at one end to a selection terminal 531 of the switch circuit 53, and connected at the other end to a selection terminal 631 of the switch circuit 63. The transmit/receive filter 35 need not necessarily be included in the radio frequency module 1.

The transmit/receive filter 36 is connected between: the antenna connection terminal 103; and the power amplifier circuit 13 and the low-noise amplifier circuit 25. The transmit/receive filter 36 is a band pass filter having a passband that includes the transmission and reception bands of Band F (F-TRx). The transmit/receive filter 36 is capable of passing signals within the transmission and reception bands of Band F, and attenuating signals outside the transmission and reception bands of Band F. The transmit/receive filter 36 is connected at one end to a selection terminal 532 of the switch circuit 53, and connected at the other end to a selection terminal 632 of the switch circuit 63. The transmit/receive filter 36 need not necessarily be included in the radio frequency module 1.

The transmit filter 37 is an example of a fourth transmit filter. The transmit filter 37 is connected between the antenna connection terminal 101 and the power amplifier circuit 11. The transmit filter 37 is a low pass filter having a passband that includes the transmission band of Band G (G-Tx). The transmit filter 37 is capable of passing signals within the transmission band of Band G, and attenuating signals outside the transmission band of Band G. The transmit filter 37 is connected at one end to a selection terminal 513 of the switch circuit 51, and connected at the other end to a selection terminal 613 of the switch circuit 61.

The transmit filter 38 is an example of a fifth transmit filter. The transmit filter 38 is connected between the antenna connection terminal 102 and the power amplifier circuit 12. The transmit filter 38 is a low pass filter having a passband that includes the transmission band of Band H (H-Tx). The transmit filter 38 is capable of passing signals within the transmission band of Band H, and attenuating signals outside the transmission band of Band H. The transmit filter 38 is connected at one end to a selection terminal 523 of the switch circuit 52, and connected at the other end to a selection terminal 623 of the switch circuit 62.

The above-mentioned filters are not limited to band pass filters and low pass filters. A subset or all of the above-mentioned filters may be band elimination filters, or may be high pass filters.

The matching circuit (matching network) 41 is connected between: the power amplifier circuit 11; and the transmit filters 311, 321, and 37. Specifically, the matching circuit 41 is connected at one end to the power amplifier circuit 11, and connected at the other end to the transmit filters 311, 321, and 37 via the switch circuit 61. The matching circuit 41 may include an inductor and/or a capacitor. The matching circuit 41 is capable of providing impedance matching between: the power amplifier circuit 11; and the transmit filters 311, 321, and 37. The matching circuit 41 need not necessarily be included in the radio frequency module 1.

The matching circuit (matching network) 42 is connected between: the power amplifier circuit 12; and the transmit filters 331, 341, and 38. Specifically, the matching circuit 42 is connected at one end to the power amplifier circuit 12, and connected at the other end to the transmit filters 331, 341, and 38 via the switch circuit 62. The matching circuit 42 may include an inductor and/or a capacitor. The matching circuit 42 is capable of providing impedance matching between: the power amplifier circuit 12; and the transmit filters 331, 341, and 38. The matching circuit 42 need not necessarily be included in the radio frequency module 1.

The matching circuit (matching network) 43 is connected between: the power amplifier circuit 13; and the transmit/receive filters 35 and 36. Specifically, the matching circuit 43 is connected at one end to the power amplifier circuit 13, and connected at the other end to the transmit/receive filters 35 and 36 via the switch circuit 63. The matching circuit 43 may include an inductor and/or a capacitor. The matching circuit 43 is capable of providing impedance matching between: the power amplifier circuit 13; and the transmit/receive filters 35 and 36. The matching circuit 43 need not necessarily be included in the radio frequency module 1.

The switch circuit 51 is connected between: the antenna connection terminal 101; and the duplexers 31 and 32 and the transmit filter 37. The switch circuit 51 includes a common terminal 510, and the selection terminals 511, 512, and 513. The common terminal 510 is connected to the antenna connection terminal 101. The selection terminal 511 is connected to the duplexer 31. The selection terminal 512 is connected to the duplexer 32. The selection terminal 513 is connected to the transmit filter 37. With the connection arrangement mentioned above, the switch circuit 51 is capable of, for example, selectively connecting the common terminal 510 to the selection terminals 511 to 513 based on a digital control signal provided from the RFIC 3. The switch circuit 51 is implemented as, for example, a single-pole triple-throw (SP3T) switch circuit.

The switch circuit 52 is connected between: the antenna connection terminal 102; and the duplexers 33 and 34 and the transmit filter 38. The switch circuit 52 includes a common terminal 520, and the selection terminals 521, 522, and 523. The common terminal 520 is connected to the antenna connection terminal 102. The selection terminal 521 is connected to the duplexer 33. The selection terminal 522 is connected to the duplexer 34. The selection terminal 523 is connected to the transmit filter 38. With the connection arrangement mentioned above, the switch circuit 52 is capable of, for example, selectively connecting the common terminal 520 to the selection terminals 521 to 523 based on a digital control signal provided from the RFIC 3. The switch circuit 52 is implemented as, for example, a SP3T switch circuit.

The switch circuit 53 is connected between: the antenna connection terminal 103; and the transmit/receive filters 35 and 36. The switch circuit 53 includes a common terminal 530, and the selection terminals 531 and 532. The common terminal 530 is connected to the antenna connection terminal 103. The selection terminal 531 is connected to the transmit/receive filter 35. The selection terminal 532 is connected to the transmit/receive filter 36. With the connection arrangement mentioned above, the switch circuit 53 is capable of, for example, selectively connecting the common terminal 530 to the selection terminals 531 and 532 based on a digital control signal provided from the RFIC 3. The switch circuit 53 is implemented as, for example, a SPDT switch circuit.

A subset or all of the switch circuits 51 to 53 need not necessarily be included in the radio frequency module 1. The switch circuit 61 is an example of a first switch circuit. The switch circuit 61 is connected between: the power amplifier circuit 11; and the transmit filters 311, 321, and 37. The switch circuit 61 includes a common terminal 610, and the selection terminals 611, 612, and 613. The common terminal 610 is an example of a first common terminal. The common terminal 610 is connected to the power amplifier circuit 11 via the matching circuit 41. The selection terminal 611 is an example of a first selection terminal. The selection terminal 611 is connected to the transmit filter 311. The selection terminal 612 is connected to the transmit filter 321. The selection terminal 612 need not necessarily be included in the switch circuit 61. The selection terminal 613 is an example of a second selection terminal. The selection terminal 613 is connected to the transmit filter 37. With the connection arrangement mentioned above, the switch circuit 61 is capable of, for example, selectively connecting the common terminal 610 to the selection terminals 611 to 613 based on a digital control signal provided from the RFIC 3. The switch circuit 61 is implemented as, for example, a SP3T switch circuit.

The switch circuit 62 is an example of a second switch circuit. The switch circuit 62 is connected between: the power amplifier circuit 12; and the transmit filters 331, 341, and 38. The switch circuit 62 includes a common terminal 620, and the selection terminals 621, 622, and 623. The common terminal 620 is an example of a second common terminal. The common terminal 620 is connected to the power amplifier circuit 12 via the matching circuit 42. The selection terminal 621 is an example of a third selection terminal. The selection terminal 621 is connected to the transmit filter 331. The selection terminal 622 is connected to the transmit filter 341. The selection terminal 622 need not necessarily be included in the switch circuit 62. The selection terminal 623 is an example of a fourth selection terminal. The selection terminal 623 is connected to the transmit filter 38. With the connection arrangement mentioned above, the switch circuit 62 is capable of, for example, selectively connecting the common terminal 620 to the selection terminals 621 to 623 based on a digital control signal provided from the RFIC 3. The switch circuit 62 is implemented as, for example, a SP3T switch circuit.

The switch circuit 63 is connected between: the power amplifier circuit 13 and the low-noise amplifier circuit 25; and the transmit/receive filters 35 and 36. The switch circuit 63 includes common terminals 630 and 633, and the selection terminals 631 and 632. The common terminal 630 is connected to the power amplifier circuit 13. The common terminal 633 is connected to the low-noise amplifier circuit 25. The selection terminal 631 is connected to the transmit/receive filter 35. The selection terminal 632 is connected to the transmit/receive filter 36. With the connection arrangement mentioned above, the switch circuit 63 is capable of, for example, selectively connecting the common terminal 630 to the selection terminals 631 and 632, and selectively connecting the common terminal 633 to the selection terminals 631 and 632, based on a digital control signal provided from the RFIC 3. Conversely speaking, the switch circuit 63 is capable of selectively connecting the selection terminal 631 to the common terminals 630 and 633, and selectively connecting the selection terminal 632 to the common terminals 630 and 633. The switch circuit 63 is implemented as, for example, a double-pole double-throw (DPDT) switch circuit.

A subset or all of the switch circuits 61 to 63 need not necessarily be included in the radio frequency module 1.

The PA control circuit 70 is capable of controlling the power amplifier circuits 11 to 13. Specifically, for example, based on a digital control signal provided from the RFIC 3, the PA control circuit 70 outputs, to the power amplifier circuits 11 to 13, control signals for controlling the power amplifier circuits 11 to 13. As a result, for example, a bias current to be supplied to each of the power amplifier circuits 11 to 13 is controlled. The PA control circuit 70 need not necessarily be included in the radio frequency module 1.

### 1.3. Frequency Bands

Frequency bands according to Embodiment 1 will now be described. Bands A to H are frequency bands for a communication system built by use of the radio access technology (RAT). Bands A to H are predefined by standardizing bodies or other entities (e.g., 3rd Generation Partnership Project (3GPP) (registered trademark) and Institute of Electrical and Electronics Engineers (IEEE)). Examples of such communication systems include 5th Generation New Radio (5G NR) systems, 4th Generation Long Term Evolution (4G LTE) systems, and 2nd Generation Global System for Mobile communications) (2G GSM) systems.

Bands A, B, and G are mutually different FDD bands included in a low-band (LB) group. Band A is an example of a first band, and Band G is an example of a fourth band. Harmonic bands of the transmission band of Band A may at least partially overlap with the transmission band of Band C. The low-band group refers to a frequency range that includes a plurality of frequency bands used for 2G GSM, 4G LTE, and 5G NR. The low-band group is an example of a first band group, and defined as a frequency range from 617 to 960 MHz. Bands A and B may be 5G NR bands or 4G LTE bands, and Band G may be a 2G GSM band. Non-limiting examples of Bands A and B may include any two bands selected from the group consisting of: Band5, Band8, Band26, and Band28 for 4G LTE; and n5, n8, n26, and n28 for 5G NR.

Bands C, D, and H are mutually different FDD bands included in a mid-band (MB) group. Band C is an example of a second band, and Band H is an example of a fifth band. The transmission band of Band C may at least partially overlap with the harmonic bands of the transmission band of Band A. The mid-band group refers to a frequency range that includes a plurality of frequency bands used for 2G GSM, 4G LTE, and 5G NR, and that is higher than the low-band group. The mid-band group is an example of a second band group, and defined as a frequency range from 1427 to 2200 MHz. Bands C and D may be 5G NR bands or 4G LTE bands, and Band H may be a 2G GSM band. Non-limiting examples of Bands C and D may include any two bands selected from the group consisting of: Band1, Band3, Band25 and Band66 for 4G LTE; and n1, n3, n25 and n66 for 5G NR.

Bands E and F are mutually different TDD bands included in a high-band (HB) group. Band E is an example of a third band. The high-band group refers to a frequency range that includes a plurality of frequency bands used for 4G LTE and 5G NR, and that is higher than the mid-band group. The high-band group is an example of a third band group, and defined as a frequency range from 2300 to 2690 MHz. Bands E and F may be 5G NR bands or 4G LTE bands. Non-limiting examples of Bands E and F may include any two bands selected from the group consisting of: Band40 and Band41 for 4G LTE; and n40 and n41 for 5G NR.

According to Embodiment 1, Bands A to D are FDD bands, and Bands E and F are TDD bands, but this does not imply any limitation. For example, Bands E and/or F may be FDD bands. In this case, the transmit/receive filters 35 and/or 36 may be replaced with duplexers. The first to third band groups are not limited to low-band, mid-band, and high-band groups, respectively. For example, a subset or all of the first to third band groups may be band groups included in Frequency Range 3 (FR3) (7.125 GHz to 24.25 GHZ) or Frequency Range 2 (FR2) (24.25 GHz to 71 GHZ). 1.4. Implementation Example of Radio Frequency Module 1

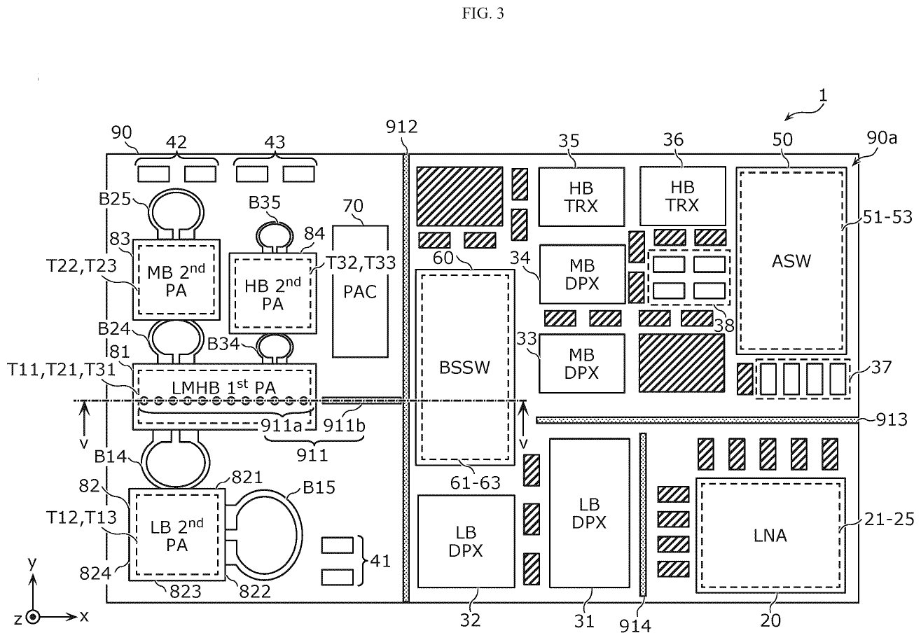

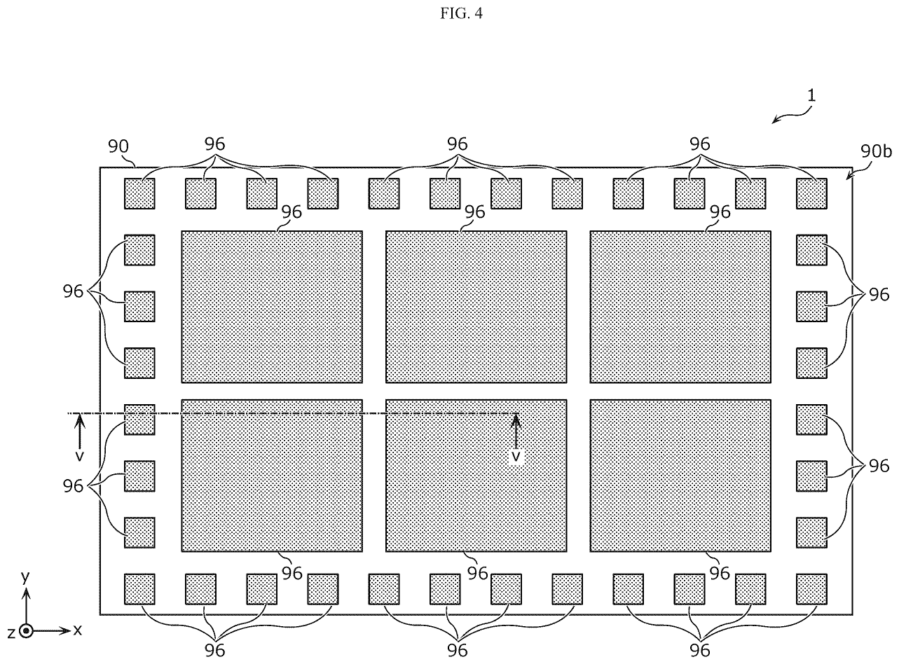

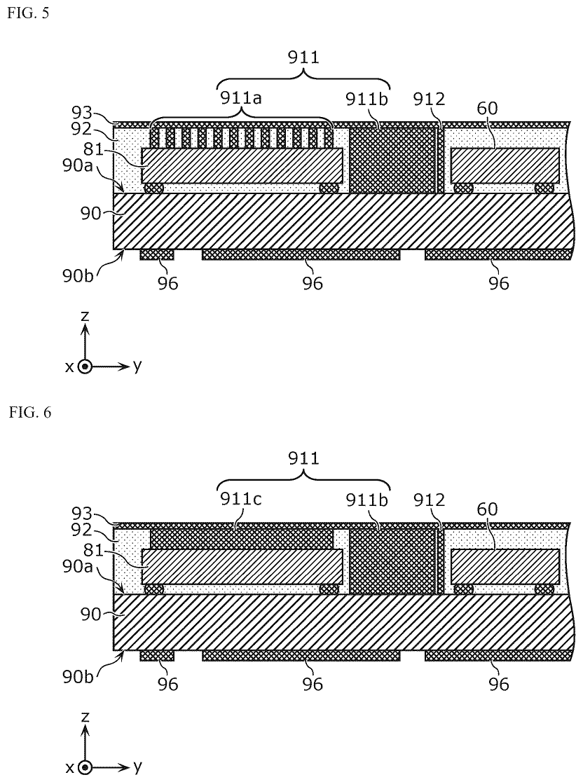

An implementation example of the radio frequency module 1 with the circuit configuration described above will now be described with reference to FIGS. 3 to 5. FIG. 3 is a plan view of the radio frequency module 1 according to Embodiment 1. FIG. 4 is a plan view of the radio frequency module 1 according to Embodiment 1, with a major face 90b of a module laminate 90 viewed in a see-through manner from the positive side of the z-axis. FIG. 5 is a partial cross-sectional view of the radio frequency module 1 according to Embodiment 1. The cross-section of the radio frequency module 1 in FIG. 5 is taken along a line v-v in each of FIGS. 3 and 4.

In FIG. 3, to facilitate understanding of the positional relationship between individual components, a resin member 92 that covers a plurality of circuit components and a metal shield 93 that covers the resin member 92 are not illustrated, and individual components are provided with labels representing the components. The actual components need not necessarily be provided with such labels. In FIG. 3, hatched components represent optional components.

FIGS. 3 to 5 each illustrate one exemplary implementation of the radio frequency module 1. The radio frequency module 1 may be implemented by using any one of a wide variety of circuit implementations and circuit technologies. Accordingly, the description of the radio frequency module 1 provided below is not to be construed restrictively.

The radio frequency module 1 includes the following components in addition to the circuit components illustrated in FIG. 2: the module laminate 90, metal shields 911, 912, 913, and 914, the resin member 92, the metal shield 93, and a plurality of external connection terminals 96.

The module laminate 90 has major faces 90a and 90b that are opposite to each other. The major faces 90a and 90b are respectively an example of a first major face and an example of a second major face. Wiring, via conductors, and other features (not illustrated) may be provided within the module laminate 90 and/or on the module laminate 90.

Suitable examples of the module laminate 90 may include, but are not limited to: a low temperature co-fired ceramic (LTCC) substrate or a high temperature co-fired ceramic (HTCC) substrate that has a multilayer structure of a plurality of dielectric layers; a component-embedded board; a substrate with a redistribution layer (RDL); and a printed circuit board.

A semiconductor component 81 is an example of a first semiconductor component. The semiconductor component 81 is disposed on, e.g., mounted on, the major face 90a of the module laminate 90. The semiconductor component 81 includes the preceding-stage amplifiers T11, T21, and T31 (LMHB 1st PA). In plan view of the module laminate 90, the semiconductor component 81 is disposed between the baluns B14 and B24, between the baluns B14 and B34, between the baluns B15 and B25, and between the baluns B15 and B35.

The semiconductor material of the semiconductor component 81 is different from the semiconductor material of each of semiconductor components 82 to 84. For example, silicon (Si) is used as the semiconductor material of the semiconductor component 81. In this case, the preceding-stage amplifiers T11, T21, and T31 may be implemented in complementary metal oxide semiconductor (CMOS), or may be manufactured by using a silicon on insulator (SOI) process.

The semiconductor component 82 is an example of a second semiconductor component. The semiconductor component 82 is disposed on the major face 90a of the module laminate 90. The semiconductor component 82 includes the subsequent-stage amplifiers T12 and T13 (LB 2nd PA). In plan view of the module laminate 90, the semiconductor component 82 has the shape of a rectangle including edges 821, 822, 823, and 824.

The edge 821 is an example of a first edge. The edge 821 is adjacent to the edges 822 and 824, and opposite to the edge 823. The edge 822 is an example of a second edge. The edge 822 is adjacent to the edges 821 and 823, and opposite to the edge 824. The edge 823 is an example of a third edge. The edge 823 is adjacent to the edges 822 and 824, and opposite to the edge 821. The edge 824 is adjacent to the edges 821 and 823, and opposite to the edge 822.

The edge 823 of the semiconductor component 82 is disposed adjacent to an edge (the lower edge in FIG. 3) of the module laminate 90 that extends in the x-direction. The edge 824 of the semiconductor component 82 is disposed adjacent to an edge (the left edge in FIG. 3) of the module laminate 90 that extends in the y-direction.

The semiconductor component 83 is an example of a third semiconductor component. The semiconductor component 83 is disposed on the major face 90a of the module laminate 90. The semiconductor component 83 includes the subsequent-stage amplifiers T22 and T23 (MB 2nd PA). In plan view of the module laminate 90, the semiconductor component 83 is disposed between the baluns B24 and B25, and between the baluns B15 and B25.

The semiconductor component 84 is an example of a fourth semiconductor component. The semiconductor component 84 is disposed on the major face 90a of the module laminate 90. The semiconductor component 84 includes the subsequent-stage amplifiers T32 and T33 (HB 2nd PA). In plan view of the module laminate 90, the semiconductor component 84 is disposed between the baluns B34 and B35, and between the baluns B15 and B35.

The semiconductor material of each of the semiconductor components 82 to 84 is different from the semiconductor material of the semiconductor component 81. For example, silicon germanium (SiGe) or gallium arsenide (GaAs) may be used as the semiconductor material of each of the semiconductor components 82 to 84. In this case, the subsequent-stage amplifiers T12, T13, T22, T23, T32, and T33 may be implemented as heterojunction bipolar transistors (HBTs). Gallium nitride (GaN) or silicon carbonate (Sic) may be used as the semiconductor material of each of the semiconductor components 82 to 84. In this case, the subsequent-stage amplifiers T12, T13, T22, T23, T32, and T33 may be implemented as high electron mobility transistors (HEMTs) or metal-semiconductor field effect transistors (MESFETs). The semiconductor components 83 and 84 may be integrated into a single semiconductor component.

The balun B14 is formed by a wiring pattern on the major face 90a of the module laminate 90 and/or within the module laminate 90. In plan view of the module laminate 90, the balun B14 is disposed between the semiconductor components 81 and 82, and adjacent to the edge 821 of the semiconductor component 82.

The balun B24 is formed by a wiring pattern on the major face 90a of the module laminate 90 and/or within the module laminate 90. The balun B24 is disposed between the semiconductor components 81 and 83 in plan view of the module laminate 90.

The balun B34 is formed by a wiring pattern on the major face 90a of the module laminate 90 and/or within the module laminate 90. The balun B34 is disposed between the semiconductor components 81 and 84 in plan view of the module laminate 90.

The balun B15 is formed by a wiring pattern on the major face 90a of the module laminate 90 and/or within the module laminate 90. In plan view of the module laminate 90, the balun B15 is disposed adjacent to the edge 822 of the semiconductor component 82.

The balun B25 is formed by a wiring pattern on the major face 90a of the module laminate 90 and/or within the module laminate 90. The balun B25 is disposed between the semiconductor component 83 and the matching circuit 42 in plan view of the module laminate 90. This makes it possible to shorten the wiring that connects the subsequent-stage amplifiers T22 and T23 to the matching circuit 42 via the balun B25.

The balun B35 is formed by a wiring pattern on the major face 90a of the module laminate 90 and/or within the module laminate 90. The balun B35 is disposed between the semiconductor component 84 and the matching circuit 43 in plan view of the module laminate 90. This makes it possible to shorten the wiring that connects the subsequent-stage amplifiers T32 and T33 to the matching circuit 43 via the balun B35.

A subset or all of the baluns B14, B15, B24, B25, B34, and B35 may be implemented as surface mount devices (SMDs).

The matching circuits 41 to 43 are implemented on the major face 90a of the module laminate 90 by using chip inductors and/or chip capacitors. The matching circuits 41 to 43 may be implemented by using integrated passive devices (IPDs), instead of or in addition to chip inductors and/or chip capacitors.

A semiconductor component 20 is disposed on the major face 90a of the module laminate 90. The semiconductor component 20 includes the low-noise amplifier circuits 21 to 25 (LNA).

For example, single-crystal silicon (Si), gallium nitride (GaN), or silicon carbonate (SiC) may be used as the semiconductor material of the semiconductor component 20. In this case, a subset or all of a plurality of amplifying transistors included in the semiconductor component 20 may be field effect transistors (FETs). Bipolar transistors may be used instead of FETs. The semiconductor component 20 may be divided into a plurality of semiconductor components.

The duplexers 31 and 32 (LB DPX), the duplexers 33 and 34 (MB DPX), the transmit/receive filters 35 and 36 (HB TRX), and the transmit filters 37 and 38 are disposed on the major face 90a of the module laminate 90. The duplexers 31 to 34, the transmit/receive filters 35 and 36, and the transmit filters 37 and 38 may be, but are not limited to, surface acoustic wave (SAW) filters, bulk acoustic wave (BAW) filters, LC filters, or dielectric filters, or any combination thereof.

A semiconductor component 50 is disposed on the major face 90a of the module laminate 90. The semiconductor component 50 includes the switch circuits 51 to 53 (ASW).

A semiconductor component 60 is disposed on the major face 90a of the module laminate 90. The semiconductor component 60 includes the switch circuits 61 to 63 (BSSW).

The PA control circuit 70 (PAC) is disposed on the major face 90a of the module laminate 90. The PA control circuit 70 is connected, via wiring (not illustrated) within the module laminate 90 and/or on the module laminate 90, to the digital control terminal 130 included in each of the external connection terminals 96.

A metal shield 911 is connected to ground, and disposed on the major face 90a of the module laminate 90. In plan view of the module laminate 90, the metal shield 911 is disposed between: the baluns B14 and B15; and the baluns B24, B25, B34, and B35. This configuration allows the metal shield 911 to reduce coupling between: the baluns B14 and B15; and the baluns B24, B25, B34, and B35. In particular, since all or a subset of harmonic bands of the transmission bands of Bands A and B included in the low-band group may overlap with the transmission bands of Bands C and D included in the mid-band group and with the transmission bands of Bands E and F included in the high-band group, the reduction of coupling between: the baluns B14 and B15; and the baluns B24, B25, B34, and B35 effectively leads to a significant improvement in the quality of transmission signals.

The metal shield 911 includes bonding wires 911a, and a metal wall 911b. The bonding wires 911a are arranged in the x-direction on the semiconductor component 81. The bonding wires 911a extend from the semiconductor component 81 toward the metal shield 93, and are connected to the metal shield 93. The metal wall 911b is provided on the major face 90a of the module laminate 90, and connected at its distal end to the metal shield 93. The metal wall 911b extends in the direction of arrangement of the bonding wires 911a (x-direction) from the lateral side of the semiconductor component 81.

The metal shield 912 is a metal wall provided on the major face 90a of the module laminate 90, and connected to ground. In plan view of the module laminate 90, the metal shield 912 is disposed between: the power amplifier circuits 11 to 13 and the matching circuits 41 to 43; and the low-noise amplifier circuits 21 to 25, the duplexers 31 to 34, the transmit/receive filters 35 and 36, the transmit filters 37 and 38, and the switch circuits 51 to 53 and 61 to 63. This configuration allows the metal shield 912 to reduce coupling of the matching circuits 41 to 43 and other components with a circuit component on the receive path, and consequently improve the isolation between the transmit path and the receive path.

The metal shield 913 is a metal wall provided on the major face 90a of the module laminate 90, and connected to ground. In plan view of the module laminate 90, the metal shield 913 is disposed between: the duplexers 31 and 32; and the duplexers 33 and 34, and between: the duplexers 31 and 32; and the transmit/receive filters 35 and 36. This configuration allows the metal shield 913 to reduce leakage of harmonics of Bands A and B, which are included in the low-band group, into the paths for signals of Bands C to F, which are included in the mid-band group and the high-band group.

The metal shield 914 is a metal wall provided on the major face 90a of the module laminate 90, and connected to ground. In plan view of the module laminate 90, the metal shield 914 is disposed between: the low-noise amplifier circuits 21 to 25; and the duplexers 31 and 32. This configuration allows the metal shield 914 to provide isolation for the low-noise amplifier circuits 21 to 25 to improve the noise figure (NF).

An example of the metal material of each of the metal shields 911 to 914 may be, but is not limited to, copper or aluminum. A subset or all of the metal shields 911 to 914 need not necessarily be included in the radio frequency module 1.

The resin member 92 covers at least part of the major face 90a of the module laminate 90 and at least a subset of components on the major face 90a. An example of the material of the resin member 92 may be, but is not limited to, epoxy resin. The resin member 92 serves to ensure reliability such as mechanical strength and moisture resistance of components on the major face 90a. The resin member 92 need not necessarily be included in the radio frequency module 1.

The metal shield 93 is formed as a metallic thin film on the surface of the resin member 92 by, for example, sputtering. The metal shield 93 is provided so as to cover at least part of the surface (the top and lateral faces) of the resin member 92. The metal shield 93 is connected to the metal shields 911 to 914. The metal shield 93 is connected to ground. The metal shield 93 makes it possible to reduce the entry of external noise into an electronic component constituting the radio frequency module 1, and reduce the interference of noise generated in the radio frequency module 1 with another module or another apparatus. The metal shield 93 need not necessarily be included in the radio frequency module 1.

The external connection terminals 96 include the antenna connection terminals 101 to 103, the radio frequency input terminals 111 to 113, the radio frequency output terminals 121 to 125, the digital control terminal 130, and a ground terminal. The external connection terminals 96 are connected, at locations outside the radio frequency module 1, to components such as an input/output terminal and/or a ground terminal on a mother board (not illustrated) disposed in the negative direction of the z-axis of the radio frequency module 1. The external connection terminals 96 are connected, at locations inside the radio frequency module 1, to components on the major face 90a by use of, for example, via conductors provided within the module laminate 90.

### 1.5. Concluding Remarks

As described above, the radio frequency module 1 according to Embodiment 1 includes the module laminate 90, and the power amplifier circuits 11 and 12. The module laminate 90 has the major faces 90a and 90b that are opposite to each other. The power amplifier circuits 11 and 12 are disposed at the module laminate 90. The power amplifier circuit 11 includes the preceding-stage amplifier T11, two subsequent-stage amplifiers T12 and T13, and the balun B14. The balun B14 is connected between: the preceding-stage amplifier T11; and the two subsequent-stage amplifiers T12 and T13. The power amplifier circuit 12 includes the preceding-stage amplifier T21, two subsequent-stage amplifiers T22 and T23, and the balun B24. The balun B24 is connected between: the preceding-stage amplifier T21; and the two subsequent-stage amplifiers T22 and T23. The preceding-stage amplifier T11 and the preceding-stage amplifier T21 are included in the semiconductor component 81 disposed at the module laminate 90. The two subsequent-stage amplifiers T12 and T13 are included in the semiconductor component 82 disposed at the module laminate 90. The two subsequent-stage amplifiers T22 and T23 are included in the semiconductor component 83 disposed at the module laminate 90. The semiconductor component 81 is disposed between the baluns B14 and B24 in plan view of the module laminate 90.

According to the configuration mentioned above, the preceding-stage amplifiers T11 and T21 can be collectively incorporated into the semiconductor component 81, and the subsequent-stage amplifiers T12 and T13 and the subsequent-stage amplifiers T22 and T23 can be individually incorporated into the semiconductor components 82 and 83, respectively, which are different from the semiconductor component 81. Accordingly, the semiconductor components 82 and 83, which are suited for high output power applications, can be used for the subsequent-stage amplifiers T12, T13, T22, and T23, which are required to deliver high output power. Conversely, for example, the semiconductor component 81, which is a low-cost component, can be used for the preceding-stage amplifiers T11 and T21, which are not required to deliver high output power. In the radio frequency module 1 including the semiconductor components 81 to 83 as described above, the semiconductor component 81 is disposed between the baluns B14 and B24 in plan view of the module laminate 90. As a result, the balun B14 included in the power amplifier circuit 11 can be placed at a relatively large distance from the balun B24 included in the power amplifier circuit 12. This makes it possible to reduce coupling between the baluns B14 and B24, and consequently reduce degradation of the isolation between the power amplifier circuits 11 and 12. This increased physical separation directly addresses the problem of electromagnetic field coupling between the respective baluns, reducing coupling.

In one example, in the radio frequency module 1 according to Embodiment 1, the balun B14 may be disposed between the semiconductor components 81 and 82 in plan view of the module laminate 90.

According to the configuration mentioned above, the balun B14, which is connected between: the preceding-stage amplifier T11 included in the semiconductor component 81; and the subsequent-stage amplifiers T12 and T13 included in the semiconductor component 82, is disposed between the semiconductor components 81 and 82 in plan view of the module laminate 90. This makes it possible to shorten the wiring that connects the preceding-stage amplifier T11 to the balun B14 and the wiring that connects the balun B14 to the subsequent-stage amplifiers T12 and T13, and consequently reduce loss due to wiring resistance and mismatching loss due to stray capacitance of wiring.

In one example, in the radio frequency module 1 according to Embodiment 1, the balun B24 may be disposed between the semiconductor components 81 and 83 in plan view of the module laminate 90.

According to the configuration mentioned above, the balun B24, which is connected between: the preceding-stage amplifier T21 included in the semiconductor component 81; and the subsequent-stage amplifiers T22 and T23 included in the semiconductor component 83, is disposed between the semiconductor components 81 and 83 in plan view of the module laminate 90. This makes it possible to shorten the wiring that connects the preceding-stage amplifier T21 to the balun B24 and the wiring that connects the balun B24 to the subsequent-stage amplifiers T22 and T23, and consequently reduce loss due to wiring resistance and mismatching loss due to stray capacitance of wiring.

In one example, the radio frequency module 1 according to Embodiment 1 may further include the transmit filter 311, and the transmit filter 331. The transmit filter 311 may be connected to the power amplifier circuit 11, and have a passband including a transmission band of Band A included in the low-band group. The transmit filter 331 may be connected to the power amplifier circuit 12, and have a passband including a transmission band of Band C included in the mid-band group higher than the low-band group. Harmonic bands of the transmission band of Band A may at least partially overlap with the transmission band of Band C.

According to the configuration mentioned above, harmonic bands of the transmission band of Band A at least partially overlap with the transmission band of Band C. In such a case, when harmonics of the transmission signal of Band A leak into the path for the transmission signal of Band C, this significantly affects quality degradation of the transmission signal of Band C. Therefore, reducing degradation of the insolation between the power amplifier circuit 11, which amplifies the transmission signal of Band A, and the power amplifier circuit 12, which amplifies the transmission signal of Band C, allows for more effective reduction of the quality degradation of the transmission signal of Band C.

In one example, the radio frequency module 1 according to Embodiment 1 may further include the power amplifier circuit 13. The power amplifier circuit 13 may include the preceding-stage amplifier T31, two subsequent-stage amplifiers T32 and T33, and the balun B34 connected between: the preceding-stage amplifier T31; and the two subsequent-stage amplifiers T32 and T33. The semiconductor component 81 may further include the preceding-stage amplifier T31. The subsequent-stage amplifiers T32 and T33 may be included in the semiconductor component 84 disposed at the module laminate 90. The semiconductor component 81 may be disposed between the balun B14 and the balun B34 in plan view of the module laminate 90.

According to the configuration mentioned above, the semiconductor component 81 is disposed between the baluns B14 and B34 in plan view of the module laminate 90. As a result, the balun B14 included in the power amplifier circuit 11 can be placed at a relatively large distance from the balun B34 included in the power amplifier circuit 13. This makes it possible to reduce coupling between the baluns B14 and B34, and consequently reduce degradation of the isolation between the power amplifier circuits 11 and 13.

In one example, the radio frequency module 1 according to Embodiment 1 may further include the transmit filter 311, the transmit filter 331, and the transmit/receive filter 35. The transmit filter 311 may be connected to the power amplifier circuit 11, and have a passband including a transmission band of Band A included in the low-band group. The transmit filter 331 may be connected to the power amplifier circuit 12, and have a passband including a transmission band of Band C included in the mid-band group higher than the low-band group. The transmit/receive filter 35 may be connected to the power amplifier circuit 13, and have a passband including a transmission band of Band E included in the high-band group higher than the mid-band group. Harmonic bands of the transmission band of Band A may at least partially overlap with the transmission band of Band E.

According to the configuration mentioned above, harmonic bands of the transmission band of Band A at least partially overlap with the transmission band of Band E. In such a case, when harmonics of the transmission signal of Band A leak into the path for the transmission signal of Band E, this significantly affects quality degradation of the transmission signal of Band E. Therefore, reducing degradation of the insolation between the power amplifier circuit 11, which amplifies the transmission signal of Band A, and the power amplifier circuit 13, which amplifies the transmission signal of Band E, allows for more effective reduction of the quality degradation of the transmission signal of Band E.

In one example, in the radio frequency module 1 according to Embodiment 1, the balun B34 may be disposed between the semiconductor components 81 and 84 in plan view of the module laminate 90.

According to the configuration mentioned above, the balun B34, which is connected between the preceding-stage amplifier T31 included in the semiconductor component 81 and the subsequent-stage amplifiers T32 and T33 included in the semiconductor component 84, is disposed between the semiconductor components 81 and 84 in plan view of the module laminate 90. This makes it possible to shorten the wiring that connects the preceding-stage amplifier T31 to the balun B34 and the wiring that connects the balun B34 to the subsequent-stage amplifiers T32 and T33, and consequently reduce loss due to wiring resistance and mismatching loss due to stray capacitance of wiring.

In one example, the radio frequency module 1 according to Embodiment 1 may further include the transmit filter 311, the transmit filter 37, and the switch circuit 61. The transmit filter 311 may have a passband including a transmission band of Band A included in the low-band group. The transmit filter 37 may have a passband including a transmission band of Band G included in the low-band group. The switch circuit 61 may include the common terminal 610 that is connected to the power amplifier circuit 11, the selection terminal 611 that is connected to the transmit filter 311, and the selection terminal 613 that is connected to the transmit filter 37. Band A may be a 5G NR band or a 4G LTE band. Band G may be a 2G GSM band.

According to the configuration mentioned above, the power amplifier circuit 11 for the low-band group is capable of performing both the amplification of the transmission signal of a 5G NR band or a 4G LTE band and the amplification of the transmission signal of a 2G GSM band. This allows the radio frequency module 1 to have a reduced number of power amplifier circuits compared with radio frequency modules that include separate power amplifier circuits individually for a 5G NR band or a 4G LTE band and for a 2G GSM band.

In one example, the radio frequency module 1 according to Embodiment 1 may further include the transmit filter 331, the transmit filter 38, and the switch circuit 62. The transmit filter 331 may have a passband including a transmission band of Band C included in the mid-band group. The transmit filter 38 may have a passband including a transmission band of Band H included in the mid-band group. The switch circuit 62 may include the common terminal 620 that is connected to the power amplifier circuit 12, the selection terminal 621 that is connected to the transmit filter 331, and the selection terminal 623 that is connected to the transmit filter 38. Band C may be a 5G NR band or a 4G LTE band. Band H may be a 2G GSM band.

According to the configuration mentioned above, the power amplifier circuit 12 for the mid-band group is capable of performing both the amplification of the transmission signal of a 5G NR band or a 4G LTE band and the amplification of the transmission signal of a 2G GSM band. This allows the radio frequency module 1 to have a reduced number of power amplifier circuits compared with radio frequency modules that include separate power amplifier circuits individually for a 5G NR band or a 4G LTE band and for a 2G GSM band.

In one example, in the radio frequency module 1 according to Embodiment 1, the power amplifier circuit 11 may further include the balun B15 connected to an output terminal of each of the two subsequent-stage amplifiers T12 and T13, the power amplifier circuit 12 may further include the balun B25 connected to an output terminal of each of the two subsequent-stage amplifiers T22 and T23, and the semiconductor components 81 and 83 may be disposed between the baluns B15 and B25 in plan view of the module laminate 90.

According to the configuration mentioned above, the semiconductor components 81 and 83 are disposed between the baluns B15 and B25 in plan view of the module laminate 90. As a result, the balun B15 included in the power amplifier circuit 11 can be placed at a relatively large distance from the balun B25 included in the power amplifier circuit 12. This makes it possible to reduce coupling between the baluns B15 and B25, and consequently reduce degradation of the isolation between the power amplifier circuits 11 and 12. In particular, since transmission signals with higher power are transmitted to the baluns B15 and B25 respectively connected to the output terminals of the subsequent-stage amplifiers T12 and T13 and the output terminals of the subsequent-stage amplifiers T22 and T23, the reduction of coupling between the baluns B15 and B25 effectively leads to significantly reduced degradation of the isolation between the power amplifier circuits 11 and 12.

In one example, in the radio frequency module 1 according to Embodiment 1, the power amplifier circuit 11 may further include the balun B15 connected to an output terminal of each of the two subsequent-stage amplifiers T12 and T13, the power amplifier circuit 13 may further include the balun B35 connected to an output terminal of each of the two subsequent-stage amplifiers T32 and T33, and the semiconductor components 81 and 84 may be disposed between the baluns B15 and B35 in plan view of the module laminate 90.

According to the configuration mentioned above, the semiconductor components 81 and 84 are disposed between the baluns B15 and B35 in plan view of the module laminate 90. As a result, the balun B15 included in the power amplifier circuit 11 can be placed at a relatively large distance from the balun B35 included in the power amplifier circuit 13. This makes it possible to reduce coupling between the baluns B15 and B35, and consequently reduce degradation of the isolation between the power amplifier circuits 11 and 13. In particular, since transmission signals with higher power are transmitted to the baluns B15 and B35 respectively connected to the output terminals of the subsequent-stage amplifiers T12 and T13 and the output terminals of the subsequent-stage amplifiers T32 and T33, the reduction of coupling between the baluns B15 and B35 effectively leads to significantly reduced degradation of the isolation between the power amplifier circuits 11 and 13.

In one example, in the radio frequency module 1 according to Embodiment 1, the power amplifier circuit 11 may further include the balun B15 connected to an output terminal of each of the two subsequent-stage amplifiers T12 and T13, the semiconductor component 82 may have a rectangular shape in plan view of the module laminate 90, the balun B14 may be disposed adjacent to the edge 821 of the semiconductor component 82 in plan view of the module laminate 90, and the balun B15 may be disposed adjacent to the edge 822, which is an edge of the semiconductor component 82 adjacent to the edge 821, in plan view of the module laminate 90.

According to the configuration mentioned above, the baluns B14 and B15 are disposed adjacent to two mutually adjacent edges 821 and 822 of the semiconductor component 82, respectively. Accordingly, when the edges 823 and 824 of the semiconductor component 82, which are respectively opposite to the edges 821 and 822, are placed along mutually adjacent edges of the module laminate 90, the semiconductor component 82 can be positioned close to a vertex of the module laminate 90. This configuration makes it possible to improve the flexibility in the layout of other components. In particular, since the baluns B14 and B15 included in the power amplifier circuit 11 used for the low-band group are larger in size than the baluns B24 and B25 included in the power amplifier circuit 12 used for the mid-band group, the above-mentioned configuration effectively leads to significantly improved flexibility in the layout of other components.

In one example, in the radio frequency module 1 according to Embodiment 1, the semiconductor material of the semiconductor component 81 may be different from the semiconductor material of each of the semiconductor components 82 and 83.

According to the configuration mentioned above, a semiconductor material suited for high output power applications can be used for the semiconductor components 82 and 83 including the subsequent-stage amplifiers T12, T13, T22, and T23, which are required to deliver high output power, and conversely, a low-cost semiconductor material can be used for the semiconductor component 81 including the preceding-stage amplifiers T11 and T21, which are not required to deliver high output power. This makes it possible to achieve balance between high output power and low cost.

In one example, in the radio frequency module 1 according to Embodiment 1, the semiconductor material of the semiconductor component 81 may be silicon (Si), and the semiconductor material of each of the semiconductor components 82 and 83 may be gallium arsenide (GaAs).

According to the configuration mentioned above, gallium arsenide, which is a semiconductor material suited for high output power applications, can be used for the semiconductor components 82 and 83 including the subsequent-stage amplifiers T12, T13, T22, and T23, which are required to deliver high output power, and conversely, silicon, which is a low-cost semiconductor material, can be used for the semiconductor component 81 including the preceding-stage amplifiers T11 and T21, which are not required to deliver high output power.

In one example, the radio frequency module 1 according to Embodiment 1 may further include the metal shield 911 disposed between the baluns B14 and B24 in plan view of the module laminate 90.

The configuration mentioned above makes it possible to further reduce coupling between the baluns B14 and B24, and consequently further reduce degradation of the isolation between the power amplifier circuits 11 and 12.

In one example, in the radio frequency module 1 according to Embodiment 1, the metal shield 911 may include the bonding wires 911a disposed on the semiconductor component 81.

The configuration mentioned above allows the metal shield 911 to be provided also on the semiconductor component 81 by means of the bonding wires 911a.

### Modification 1 of Embodiment 1

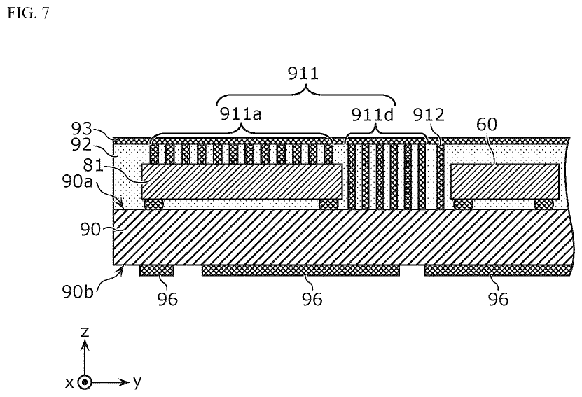

Modification 1 of Embodiment 1 will now be described. Modification 1 differs from Embodiment 1 mentioned above mainly in the configuration of the metal shield 911. The radio frequency module 1 according to Modification 1 will be described below with reference to FIG. 6, with focus on differences from Embodiment 1 mentioned above.

FIG. 6 is a partial cross-sectional view of the radio frequency module 1 according to Modification 1. The cross-section of the radio frequency module 1 in FIG. 6 corresponds to the cross-section taken along the line v-v in each of FIGS. 3 and 4. FIG. 6 illustrates one exemplary implementation of the radio frequency module 1. The radio frequency module 1 may be implemented by using any one of a wide variety of circuit implementations and circuit technologies. Accordingly, the description of the radio frequency module 1 provided below is not to be construed restrictively.

The metal shield 911 according to Modification 1 includes a metal wall 911c instead of the bonding wires 911a. The metal wall 911c is provided on the semiconductor component 81, and connected at its distal end to the metal shield 93. The metal wall 911c extends in the x-direction.

As described above, in the radio frequency module 1 according to Modification 1, the metal shield 911 may include the metal wall 911c disposed on the semiconductor component 81.

The configuration mentioned above allows the metal shield 911 to be provided also on the semiconductor component 81 by means of the metal wall 911c.

### Modification 2 of Embodiment 1

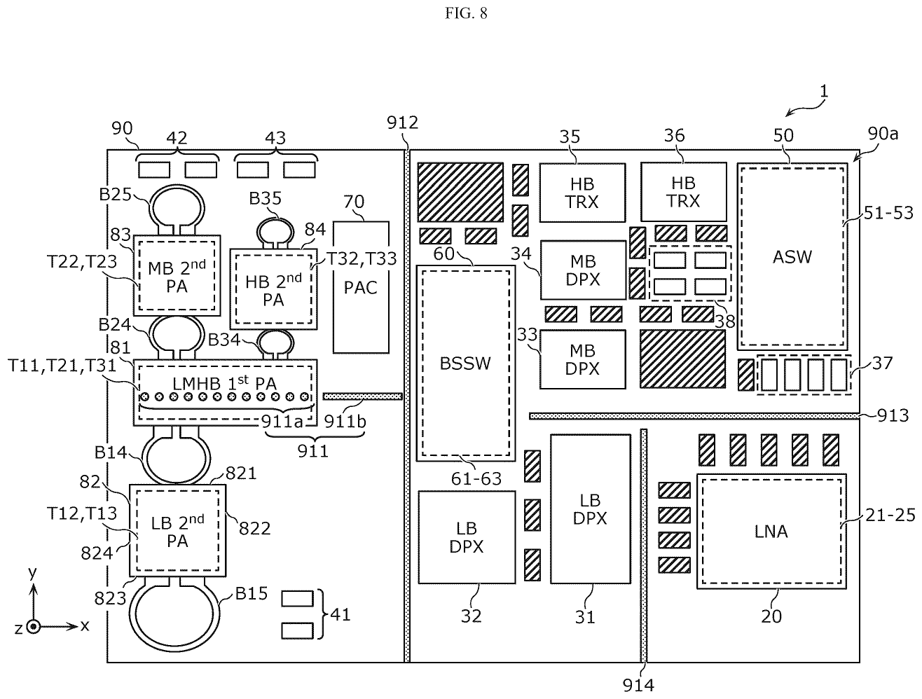

Modification 2 of Embodiment 1 will now be described. Modification 2 differs from Embodiment 1 mentioned above mainly in the configuration of the metal shield 911. The radio frequency module 1 according to Modification 2 will be described below with reference to FIG. 7, with focus on differences from Embodiment 1 mentioned above.

FIG. 7 is a partial cross-sectional view of the radio frequency module 1 according to Modification 2. The cross-section of the radio frequency module 1 in FIG. 7 corresponds to the cross-section taken along the line v-v in each of FIGS. 3 and 4. FIG. 7 illustrates one exemplary implementation of the radio frequency module 1. The radio frequency module 1 may be implemented by using any one of a wide variety of circuit implementations and circuit technologies. Accordingly, the description of the radio frequency module 1 provided below is not to be construed restrictively.

The metal shield 911 according to Modification 2 includes bonding wires 911d instead of the metal wall 911b. The bonding wires 911d are arranged in the x-direction on the major face 90a of the module laminate 90. The bonding wires 911d extend from the major face 90a of the module laminate 90 toward the metal shield 93, and are connected to the metal shield 93.

As described above, in the radio frequency module 1 according to Modification 2, the metal shield 911 may include the bonding wires 911d instead of the metal wall 911b.

Modification 1 and Modification 2 may be combined. That is, the metal shield 911 may include the metal wall 911c and the bonding wires 911d.

### Modification 3 of Embodiment 1

Modification 3 of Embodiment 1 will now be described. Modification 3 differs from Embodiment 1 mentioned above mainly in the positioning of the balun B15. Modification 3 will be described below with reference to FIG. 8, with focus on differences from Embodiment 1 mentioned above.

FIG. 8 is a plan view of the radio frequency module 1 according to Modification 3. In FIG. 8, to facilitate understanding of the positional relationship between individual components, the resin member 92 that covers a plurality of circuit components and the metal shield 93 that covers the resin member 92 are not illustrated, and individual components are provided with labels representing the components. The actual components need not necessarily be provided with such labels. In FIG. 8, hatched components represent optional components.

FIG. 8 illustrates one exemplary implementation of the radio frequency module 1. The radio frequency module 1 may be implemented by using any one of a wide variety of circuit implementations and circuit technologies. Accordingly, the description of the radio frequency module 1 provided below is not to be construed restrictively.

According to Modification 3, the balun B15 is disposed adjacent to the edge 823 of the semiconductor component 82 in plan view of the module laminate 90. The semiconductor component 82 is disposed between the baluns B14 and B15 in plan view of the module laminate 90.

As described above, in the radio frequency module 1 according to Modification 3, the power amplifier circuit 11 may further include the balun B15 connected to an output terminal of each of the two subsequent-stage amplifiers T12 and T13, the semiconductor component 82 may have a rectangular shape in plan view of the module laminate 90, the balun B14 may be disposed adjacent to the edge 821 of the semiconductor component 82 in plan view of the module laminate 90, and the balun B15 may be disposed adjacent to the edge 823, which is an edge of the semiconductor component 82 opposite to the edge 821, in plan view of the module laminate 90.

According to the configuration mentioned above, the baluns B14 and B15 are disposed adjacent to the two opposite edges 821 and 823 of the semiconductor component 82, respectively. As a result, the balun B14 can be placed at a relatively large distance from the balun B15. This makes it possible to reduce coupling between the baluns B14 and B15, and consequently reduce degradation of the isolation between the input and output of the power amplifier circuit 11.

### Modification 4 of Embodiment 1

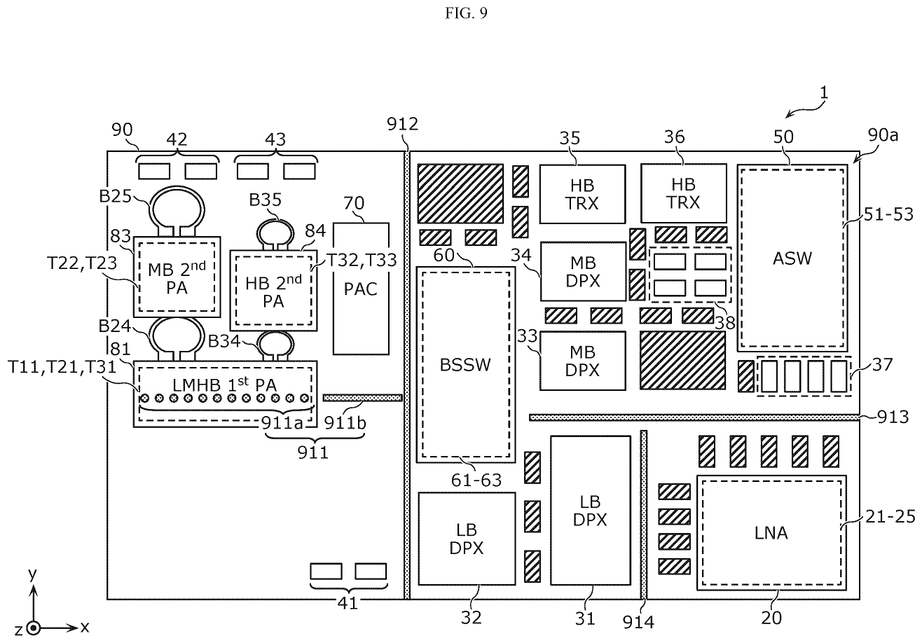

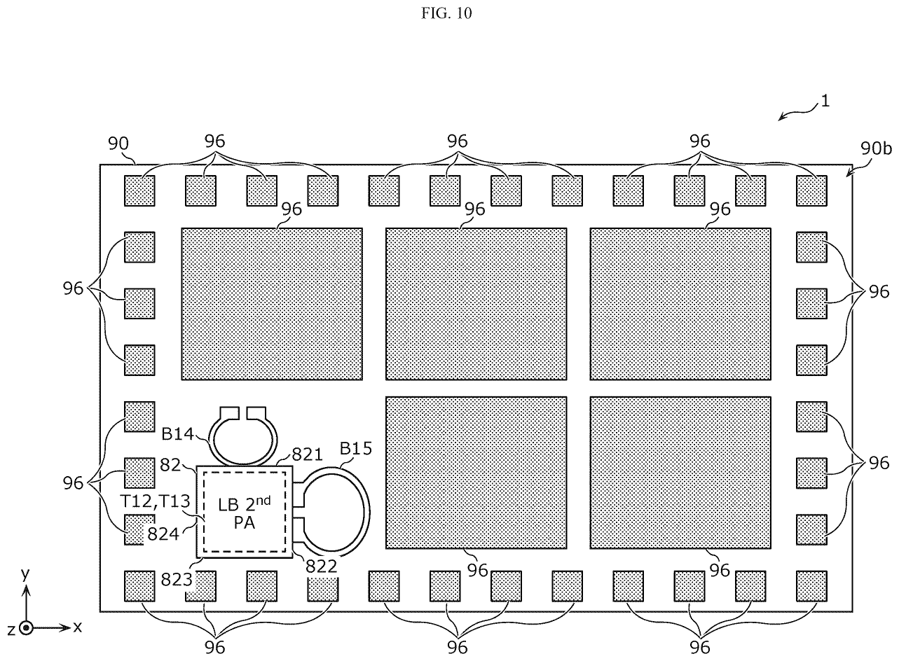

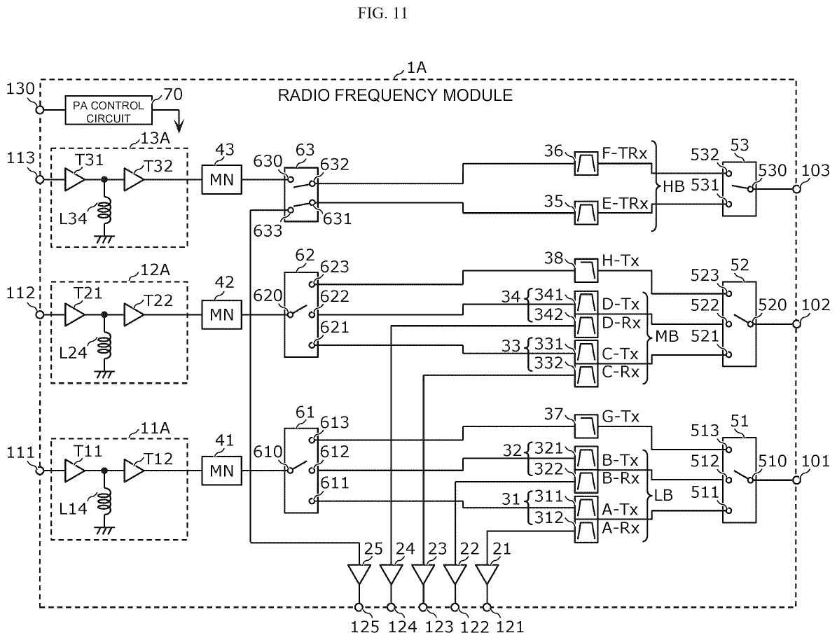

Modification 4 of Embodiment 1 will now be described. Modification 4 differs from Embodiment 1 mentioned above mainly in that the semiconductor component 82 is disposed at the major face 90b of the module laminate 90. The radio frequency module 1 according to Modification 4 will be described below with reference to FIGS. 9 and 10, with focus on differences from Embodiment 1 mentioned above.

FIG. 9 is a plan view of the radio frequency module 1 according to Modification 4. FIG. 10 is a plan view of the radio frequency module 1 according to Modification 4, with the major face 90b of the module laminate 90 viewed in a see-through manner from the positive side of the z-axis. In FIGS. 9 and 10, to facilitate understanding of the positional relationship between individual components, the resin member 92 that covers a plurality of circuit components and the metal shield 93 that covers the resin member 92 are not illustrated, and individual components are provided with labels representing the components. The actual components need not necessarily be provided with such labels. In FIG. 10, hatched components represent optional components.

FIGS. 9 and 10 each illustrate one exemplary implementation of the radio frequency module 1. The radio frequency module 1 may be implemented by using any one of a wide variety of circuit implementations and circuit technologies. Accordingly, the description of the radio frequency module 1 provided below is not to be construed restrictively.

The semiconductor component 82 is disposed on the major face 90b of the module laminate 90.

The balun B14 is formed by a wiring pattern on the major face 90b of the module laminate 90 and/or within the module laminate 90. In plan view of the module laminate 90, the balun B14 is disposed between the semiconductor components 81 and 82, and adjacent to the edge 821 of the semiconductor component 82.

The balun B15 is formed by a wiring pattern on the major face 90b of the module laminate 90 and/or within the module laminate 90. In plan view of the module laminate 90, the balun B15 is disposed adjacent to the edge 822 of the semiconductor component 82.

The edge 823 of the semiconductor component 82 is disposed adjacent to the external connection terminals 96 arranged along an edge (the lower edge in FIG. 10) of the module laminate 90 that extends in the x-direction. The edge 824 of the semiconductor component 82 is disposed adjacent to the external connection terminals 96 arranged along an edge (the left edge in FIG. 10) of the module laminate 90 that extends in the y-direction.

As described above, in the radio frequency module 1 according to Modification 4, the semiconductor component 82 may be disposed on the major face 90b of the module laminate 90, and the semiconductor component 83 may be disposed on the major face 90a of the module laminate 90.

According to the configuration mentioned above, the semiconductor component 83 and the semiconductor component 82 are disposed on different major faces 90a and 90b. This allows the module laminate 90 to be interposed between: the baluns B14 and B15, which are connected to the semiconductor component 82; and the baluns B24 and B25, which are connected to the semiconductor component 83. This in turn makes it possible to reduce coupling between: the baluns B14 and B15; and the baluns B24 and B25, and consequently reduce degradation of the isolation between the power amplifier circuits 11 and 12.

Instead of the semiconductor component 82, the semiconductor components 83 and 84 may be disposed on the major face 90b of the module laminate 90. This configuration as well makes it possible to reduce coupling between: the baluns B14 and B15; and the baluns B24, B25, B34, and B35, and consequently reduce degradation of the isolation between: the power amplifier circuit 11; and the power amplifier circuits 12 and 13.

### Embodiment 2

Embodiment 2 will now be described. Embodiment 2 differs from Embodiment 1 mentioned above mainly in that each power amplifier circuit includes an inductor instead of baluns. Embodiment 2 will be described below with reference to the drawings, with focus on differences from Embodiment 1 mentioned above.

The circuit configuration of the communication device 5 according to Embodiment 2 is similar to that of the communication device 5 according to Embodiment 1 except that the radio frequency module 1 is replaced by a radio frequency module 1A, and thus will be neither illustrated nor described in any further detail.

### 2.1. Circuit Configuration of Radio Frequency Module 1A

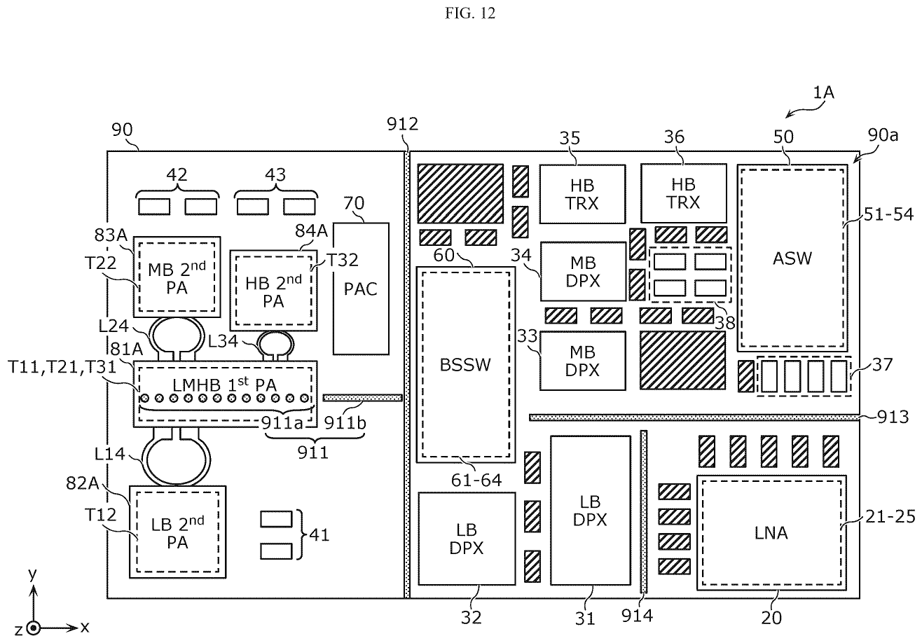

The circuit configuration of the radio frequency module 1A according to Embodiment 2 will now be described with reference to FIG. 11. FIG. 11 is a circuit diagram of the radio frequency module 1A according to Embodiment 2.

FIG. 11 illustrates an exemplary circuit configuration. The radio frequency module 1A may be implemented by using any one of a wide variety of circuit implementations and circuit technologies. Accordingly, the description of the radio frequency module 1A provided below is not to be construed restrictively.

The radio frequency module 1A includes power amplifier circuits 11A, 12A, and 13A, the low-noise amplifier circuits 21, 22, 23, 24, and 25, the duplexers 31, 32, 33, and 34, the transmit/receive filters 35 and 36, the transmit filters 37 and 38, the matching circuits 41, 42, and 43, the switch circuits 51, 52, 53, 61, 62, and 63, the antenna connection terminals 101, 102, and 103, the radio frequency input terminals 111, 112, and 113, the radio frequency output terminals 121, 122, 123, 124, and 125, and the digital control terminal 130.

The power amplifier circuit 11A is an example of a first power amplifier. The power amplifier circuit 11A is connected between the radio frequency input terminal 111 and the matching circuit 41. Specifically, the power amplifier circuit 11A includes an input terminal connected to the radio frequency input terminal 111, and an output terminal connected to the matching circuit 41. The power amplifier circuit 11A is capable of amplifying transmission signals of Bands A, B, and G by using power supplied from a power source.

According to Embodiment 2, the power amplifier circuit 11A is a multistage amplifier circuit, but is not a differential amplifier circuit. The power amplifier circuit 11A includes the preceding-stage amplifier T11, the subsequent-stage amplifier T12, and an inductor L14.

The preceding-stage amplifier T11 is an example of a first preceding-stage amplifier. The preceding-stage amplifier T11 is connected between the radio frequency input terminal 111 and the subsequent-stage amplifier T12. Specifically, the preceding-stage amplifier T11 includes an input terminal connected to the radio frequency input terminal 111, and an output terminal connected to the input terminal of the subsequent-stage amplifier T12.

The subsequent-stage amplifier T12 is an example of a first subsequent-stage amplifier. The subsequent-stage amplifier T12 is connected between the preceding-stage amplifier T11 and the matching circuit 41. Specifically, the subsequent-stage amplifier T12 includes an input terminal connected to the output terminal of the preceding-stage amplifier T11, and an output terminal connected to the matching circuit 41.

The inductor L14 is an example of a first inductor. The inductor L14 is connected between: a path that connects the preceding-stage amplifier T11 and the subsequent-stage amplifier T12 to each other; and ground. Specifically, the inductor L14 is connected at one end to the path that connects the preceding-stage amplifier T11 and the subsequent-stage amplifier T12 to each other, and connected at the other end to ground.

The power amplifier circuit 12A is an example of a second power amplifier. The power amplifier circuit 12A is connected between the radio frequency input terminal 112 and the matching circuit 42. Specifically, the power amplifier circuit 12A includes an input terminal connected to the radio frequency input terminal 112, and an output terminal connected to the matching circuit 42. The power amplifier circuit 12A is capable of amplifying transmission signals of Bands C, D, and H by using power supplied from a power source (not illustrated).

According to Embodiment 2, the power amplifier circuit 12A is a multistage amplifier circuit, but is not a differential amplifier circuit. The power amplifier circuit 12A includes the preceding-stage amplifier T21, the subsequent-stage amplifier T22, and an inductor L24.

The preceding-stage amplifier T21 is an example of a second preceding-stage amplifier. The preceding-stage amplifier T21 is connected between the radio frequency input terminal 112 and the subsequent-stage amplifier T22. Specifically, the preceding-stage amplifier T21 includes an input terminal connected to the radio frequency input terminal 112, and an output terminal connected to the input terminal of the subsequent-stage amplifier T22.

The subsequent-stage amplifier T22 is an example of a second subsequent-stage amplifier. The subsequent-stage amplifier T22 is connected between the preceding-stage amplifier T21 and the matching circuit 42. Specifically, the subsequent-stage amplifier T22 includes an input terminal connected to the output terminal of the preceding-stage amplifier T21, and an output terminal connected to the matching circuit 42.

The inductor L24 is an example of a second inductor. The inductor L24 is connected between: a path that connects the preceding-stage amplifier T21 and the subsequent-stage amplifier T22 to each other; and ground. Specifically, the inductor L24 is connected at one end to the path that connects the preceding-stage amplifier T21 and the subsequent-stage amplifier T22 to each other, and connected at the other end to ground.

The power amplifier circuit 13A is connected between the radio frequency input terminal 113 and the matching circuit 43. Specifically, the power amplifier circuit 13A includes an input terminal connected to the radio frequency input terminal 113, and an output terminal connected to the matching circuit 43. The power amplifier circuit 13A is capable of amplifying transmission signals of Bands E and F by using power supplied from a power source (not illustrated).

According to Embodiment 2, the power amplifier circuit 13A is a multistage amplifier circuit, but is not a differential amplifier circuit. The power amplifier circuit 13A includes the preceding-stage amplifier T31, the subsequent-stage amplifier T32, and an inductor L34.

The preceding-stage amplifier T31 is connected between the radio frequency input terminal 113 and the subsequent-stage amplifier T32. Specifically, the preceding-stage amplifier T31 includes an input terminal connected to the radio frequency input terminal 113, and an output terminal connected to the input terminal of the subsequent-stage amplifier T32.

The subsequent-stage amplifier T32 is connected between the preceding-stage amplifier T31 and the matching circuit 43. Specifically, the subsequent-stage amplifier T32 includes an input terminal connected to the output terminal of the preceding-stage amplifier T31, and an output terminal connected to the matching circuit 43.

The inductor L34 is connected between: a path that connects the preceding-stage amplifier T31 and the subsequent-stage amplifier T32 to each other; and ground. Specifically, the inductor L34 is connected at one end to the path that connects the preceding-stage amplifier T31 and the subsequent-stage amplifier T32 to each other, and connected at the other end to ground.

### 2.2. Implementation Example of Radio Frequency Module 1A

An implementation example of the radio frequency module 1A with the circuit configuration described above will now be described with reference to FIG. 12. FIG. 12 is a plan view of the radio frequency module 1A according to Embodiment 2.

In FIG. 12, to facilitate understanding of the positional relationship between individual components, the resin member 92 that covers a plurality of circuit components and the metal shield 93 that covers the resin member 92 are not illustrated, and individual components are provided with labels representing the components. The actual components need not necessarily be provided with such labels. In FIG. 12, hatched components represent optional components.

FIG. 12 illustrates one exemplary implementation of the radio frequency module 1A. The radio frequency module 1A may be implemented by using any one of a wide variety of circuit implementations and circuit technologies. Accordingly, the description of the radio frequency module 1A provided below is not to be construed restrictively.

A semiconductor component 81A is an example of a first semiconductor component. The semiconductor component 81A is disposed on the major face 90a of the module laminate 90. The semiconductor component 81A includes the preceding-stage amplifiers T11, T21, and T31 (LMHB 1st PA). In plan view of the module laminate 90, the semiconductor component 81A is disposed between the inductors L14 and L24, and between the inductors L14 and L34.

The semiconductor material of the semiconductor component 81A is different from the semiconductor material of each of semiconductor components 82A to 84A. For example, silicon (Si) is used as the semiconductor material of the semiconductor component 81A. In this case, the preceding-stage amplifiers T11, T21, and T31 may be implemented in CMOS, or may be manufactured by using a SOI process.

The semiconductor component 82A is an example of a second semiconductor component. The semiconductor component 82A is disposed on the major face 90a of the module laminate 90. The semiconductor component 82A includes the subsequent-stage amplifier T12 (LB 2nd PA).

The semiconductor component 83A is an example of a third semiconductor component. The semiconductor component 83A is disposed on the major face 90a of the module laminate 90. The semiconductor component 83A includes the subsequent-stage amplifier T22 (MB 2nd PA).

The semiconductor component 84A is an example of a fourth semiconductor component. The semiconductor component 84A is disposed on the major face 90a of the module laminate 90. The semiconductor component 84A includes the subsequent-stage amplifier T32 (HB 2nd PA).

The semiconductor material of each of the semiconductor components 82A to 84A is different from the semiconductor material of the semiconductor component 81A. For example, silicon germanium (SiGe) or gallium arsenide (GaAs) may be used as the semiconductor material of each of the semiconductor components 82A to 84A. In this case, the subsequent-stage amplifiers T12, T22, and T32 may be implemented as HBTs. Gallium nitride (GaN) or silicon carbonate (SiC) may be used as the semiconductor material of each of the semiconductor components 82A to 84A. In this case, the subsequent-stage amplifiers T12, T22, and T32 may be implemented as HEMTs or MESFETs. The semiconductor components 83A and 84A may be integrated into a single semiconductor component.

The inductor L14 is formed by a wiring pattern on the major face 90a of the module laminate 90 and/or within the module laminate 90. The inductor L14 is disposed between the semiconductor components 81A and 82A in plan view of the module laminate 90.

The inductor L24 is formed by a wiring pattern on the major face 90a of the module laminate 90 and/or within the module laminate 90. The inductor L24 is disposed between the semiconductor components 81A and 83A in plan view of the module laminate 90.

The inductor L34 is formed by a wiring pattern on the major face 90a of the module laminate 90 and/or within the module laminate 90. The inductor L34 is disposed between the semiconductor components 81A and 84A in plan view of the module laminate 90.

As described above, the radio frequency module 1A according to Embodiment 2 includes the module laminate 90, and the power amplifier circuits 11A and 12A disposed at the module laminate 90. The power amplifier circuit 11A includes the preceding-stage amplifier T11, the subsequent-stage amplifier T12, and the inductor L14 connected between: the path that connects the preceding-stage amplifier T11 and the subsequent-stage amplifier T12 to each other; and ground. The power amplifier circuit 12A includes the preceding-stage amplifier T21, the subsequent-stage amplifier T22, and the inductor L24 connected between: the path that connects the preceding-stage amplifier T21 and the subsequent-stage amplifier T22 to each other; and ground. The preceding-stage amplifiers T11 and T21 are included in the semiconductor component 81A disposed at the module laminate 90. The subsequent-stage amplifier T12 is included in the semiconductor component 82A disposed at the module laminate 90. The subsequent-stage amplifier T22 is included in the semiconductor component 83A disposed at the module laminate 90. The semiconductor component 81A is disposed between the inductors L14 and L24 in plan view of the module laminate 90.

According to the configuration mentioned above, the preceding-stage amplifiers T11 and T21 can be collectively incorporated into the semiconductor component 81A, and the subsequent-stage amplifiers T12 and T22 can be individually incorporated into the semiconductor components 82A and 83A, respectively, which are different from the semiconductor component 81A. Accordingly, the semiconductor components 82A and 83A, which are suited for high output power applications, can be used for the subsequent-stage amplifiers T12 and T22, which are required to deliver high output power. Conversely, for example, the semiconductor component 81A, which is a low-cost component, can be used for the preceding-stage amplifiers T11 and T21, which are not required to deliver high output power. In the radio frequency module 1A including the semiconductor components 81A to 83A as described above, the semiconductor component 81A is disposed between the inductors L14 and L24 in plan view of the module laminate 90. As a result, the inductor L14 included in the power amplifier circuit 11A can be placed at a relatively large distance from the inductor L24 included in the power amplifier circuit 12A. This makes it possible to reduce coupling between the inductors L14 and L24, and consequently reduce degradation of the isolation between the power amplifier circuits 11A and 12A.

### Other Embodiments

Although the radio frequency module according to the present disclosure has been described above based on its embodiments, the embodiments are not intended to limit the radio frequency module according to the present disclosure. The present disclosure is intended to also encompass: other embodiments implemented by combining any constituent elements in the above embodiments; modifications obtained by modifying the above embodiments in various ways as may become apparent to those skilled in the art without departing from the scope of the present disclosure; and various apparatuses incorporating the radio frequency module mentioned above.

For example, in the circuit configurations of the radio frequency module according to the above embodiments, another circuit element, wiring, and other features may be inserted between individual circuit elements and paths connecting signal paths disclosed in the drawings. In one example, an impedance matching circuit may be connected between: the duplexers 31 to 34 and the transmit/receive filters 35 and 36; and the switch circuits 51 to 53. In another example, a coupler may be connected between: the switch circuits 51 to 53; and the antenna connection terminals 101 to 103.

In another example, the various modifications of Embodiment 1 are also applicable to Embodiment 2. Specifically, in Embodiment 2, the metal shield 911 may include the metal wall 911c, and/or may include the bonding wires 911d. In Embodiment 2, the semiconductor component 82A, and the semiconductor components 83A and 84A may be disposed on different major faces 90a and 90b of the module laminate 90.

In the above embodiments, the radio frequency modules 1 and 1A may include a transmit/receive filter for an ultra-high band group (3300 to 5000 MHz).

Characteristic features of the radio frequency module described above with reference to the embodiments are presented below.
<1>

A radio frequency module comprising:
a module laminate having a first major face and a second major face that are opposite to each other; and
a first power amplifier circuit and a second power amplifier circuit that are disposed at the module laminate,
wherein the first power amplifier circuit includes
   a first preceding-stage amplifier,
   two first subsequent-stage amplifiers, and
   a first balun connected between: the first preceding-stage amplifier; and the two first subsequent-stage amplifiers,
wherein the second power amplifier circuit includes
   a second preceding-stage amplifier,
   two second subsequent-stage amplifiers, and
   a second balun connected between: the second preceding-stage amplifier; and the two second subsequent-stage amplifiers,
wherein the first preceding-stage amplifier and the second preceding-stage amplifier are included in a first semiconductor component disposed at the module laminate,
wherein the two first subsequent-stage amplifiers are included in a second semiconductor component disposed at the module laminate,
wherein the two second subsequent-stage amplifiers are included in a third semiconductor component disposed at the module laminate, and
wherein the first semiconductor component is disposed between the first balun and the second balun in plan view of the module laminate.
<2>

The radio frequency module according to <1>,
wherein the first balun is disposed between the first semiconductor component and the second semiconductor component in plan view of the module laminate.
<3>

The radio frequency module according to <2>,
wherein the second balun is disposed between the first semiconductor component and the third semiconductor component in plan view of the module laminate.
<4>

The radio frequency module according to any one of <1> to <3>, further comprising:
a first transmit filter connected to the first power amplifier circuit, the first transmit filter having a passband that includes a transmission band of a first band included in a first band group; and
a second transmit filter connected to the second power amplifier circuit, the second transmit filter having a passband that includes a transmission band of a second band included in a second band group higher than the first band group,
wherein harmonic bands of the transmission band of the first band at least partially overlap with the transmission band of the second band.
<5>

The radio frequency module according to any one of <1> to <4>, further comprising
a third power amplifier circuit,
wherein the third power amplifier circuit includes
   a third preceding-stage amplifier,
   two third subsequent-stage amplifiers, and
   a third balun connected between: the third preceding-stage amplifier; and the two third subsequent-stage amplifiers,
wherein the first semiconductor component further includes the third preceding-stage amplifier,
wherein the two third subsequent-stage amplifiers are included in a fourth semiconductor component disposed at the module laminate, and wherein the first semiconductor component is disposed between the first balun and the third balun in plan view of the module laminate.
<6>

The radio frequency module according to <5>, further comprising:
a first transmit filter connected to the first power amplifier circuit, the first transmit filter having a passband that includes a transmission band of a first band included in a first band group;
a second transmit filter connected to the second power amplifier circuit, the second transmit filter having a passband that includes a transmission band of a second band included in a second band group higher than the first band group; and
a third transmit filter connected to the third power amplifier circuit, the third transmit filter having a passband that includes a transmission band of a third band included in a third band group higher than the second band group,
wherein harmonic bands of the transmission band of the first band at least partially overlap with the transmission band of the third band.
<7>

The radio frequency module according to <5> or <6>,
wherein the third balun is disposed between the first semiconductor component and the fourth semiconductor component in plan view of the module laminate.
<8>

The radio frequency module according to any one of <1> to <7>, further comprising:
a first transmit filter having a passband that includes a transmission band of a first band included in a first band group;
a fourth transmit filter having a passband that includes a transmission band of a fourth band included in the first band group; and
a first switch circuit including
   a first common terminal that is connected to the first power amplifier circuit,
   a first selection terminal that is connected to the first transmit filter, and
   a second selection terminal that is connected to the fourth transmit filter,
wherein the first band is a 5th Generation New Radio (5G NR) band or a 4th Generation Long Term Evolution (4G LTE) band, and
wherein the fourth band is a 2nd Generation Global System for Mobile communications (2G GSM) band.
<9>

The radio frequency module according to any one of <1> to <8>, further comprising:
a second transmit filter having a passband that includes a transmission band of a second band included in a second band group;
a fifth transmit filter having a passband that includes a transmission band of a fifth band included in the second band group; and
a second switch circuit including
   a second common terminal that is connected to the second power amplifier circuit,
   a third selection terminal that is connected to the second transmit filter, and
   a fourth selection terminal that is connected to the fifth transmit filter,
wherein the second band is a 5G NR band or a 4G LTE band, and
wherein the fifth band is a 2G GSM band.
<10>

The radio frequency module according to any one of <1> to <9>,
wherein the first power amplifier circuit further includes a fourth balun that is connected to an output terminal of each of the two first subsequent-stage amplifiers,
wherein the second power amplifier circuit further includes a fifth balun that is connected to an output terminal of each of the two second subsequent-stage amplifiers, and
wherein the first semiconductor component and the third semiconductor component are disposed between the fourth balun and the fifth balun in plan view of the module laminate.
<11>

The radio frequency module according to <5>,
wherein the first power amplifier circuit further includes a fourth balun that is connected to an output terminal of each of the two first subsequent-stage amplifiers,
wherein the third power amplifier circuit further includes a sixth balun that is connected to an output terminal of each of the two third subsequent-stage amplifiers, and
wherein the first semiconductor component and the fourth semiconductor component are disposed between the fourth balun and the sixth balun in plan view of the module laminate.
<12>

The radio frequency module according to any one of <1> to <11>,
wherein the first power amplifier circuit further includes a fourth balun that is connected to an output terminal of each of the two first subsequent-stage amplifiers,
wherein the second semiconductor component has a rectangular shape in plan view of the module laminate,
wherein the first balun is disposed adjacent to a first edge of the second semiconductor component in plan view of the module laminate, and
wherein the fourth balun is disposed adjacent to a second edge of the second semiconductor component in plan view of the module laminate, the second edge being adjacent to the first edge.
<13>

The radio frequency module according to any one of <1> to <11>,
wherein the first power amplifier circuit further includes a fourth balun that is connected to an output terminal of each of the two first subsequent-stage amplifiers,
wherein the second semiconductor component has a rectangular shape in plan view of the module laminate,
wherein the first balun is disposed adjacent to a first edge of the second semiconductor component in plan view of the module laminate, and
wherein the fourth balun is disposed adjacent to a third edge of the second semiconductor component in plan view of the module laminate, the third edge being opposite to the first edge.
<14>

The radio frequency module according to any one of <1> to <13>,
wherein a semiconductor material of the first semiconductor is different from a semiconductor material of each of the second semiconductor component and the third semiconductor component.
<15>

The radio frequency module according to <14>,
wherein the semiconductor material of the first semiconductor component is silicon (Si), and
wherein the semiconductor material of each of the second semiconductor component and the third semiconductor component is gallium arsenide (GaAs).
<16>

The radio frequency module according to any one of <1> to <15>, further comprising
a metal shield disposed between the first balun and the second balun in plan view of the module laminate.
<17>

The radio frequency module according to <16>,
wherein the metal shield includes a plurality of bonding wires disposed on the first semiconductor component.
<18>

The radio frequency module according to <16>,
wherein the metal shield includes a metal wall disposed on the first semiconductor component.
<19>

The radio frequency module according to any one of <1> to <18>,
wherein the second semiconductor component is disposed at one of the first major face and the second major face, and
wherein the third semiconductor component is disposed at an other one of the first major face and the second major face.
<20>

A radio frequency module comprising:
a module laminate; and
a first power amplifier circuit and a second power amplifier circuit that are disposed at the module laminate,
wherein the first power amplifier circuit includes
   a first preceding-stage amplifier,
   a first subsequent-stage amplifier, and
   a first inductor connected between: a path that connects the first preceding-stage amplifier and the first subsequent-stage amplifier to each other; and ground,
wherein the second power amplifier circuit includes
   a second preceding-stage amplifier,
   a second subsequent-stage amplifier, and
   a second inductor connected between: a path that connects the second preceding-stage amplifier and the second subsequent-stage amplifier to each other; and ground,
wherein the first preceding-stage amplifier and the second preceding-stage amplifier are included in a first semiconductor component disposed at the module laminate,
wherein the first subsequent-stage amplifier is included in a second semiconductor component disposed at the module laminate,
wherein the second subsequent-stage amplifier is included in a third semiconductor component disposed at the module laminate, and
wherein the first semiconductor component is disposed between the first inductor and the second inductor in plan view of the module laminate.

The scope of the present invention is indicated by the appended claims, rather than the foregoing description, and is applicable to a wide variety of communication apparatuses such as mobile phones, as a radio frequency module disposed at the front-end part of such communication apparatuses.

What is claimed is:

1. A radio frequency module comprising:
a module laminate;
a first semiconductor component disposed on the module laminate;
a second semiconductor component disposed on the module laminate;
a third semiconductor component disposed on the module laminate;
a first power amplifier circuit including a first preceding-stage amplifier in the first semiconductor component, a first subsequent-stage amplifier included in the second semiconductor component, and a first passive component connected between the first preceding-stage amplifier and the first subsequent-stage amplifier; and
a second power amplifier circuit including a second preceding-stage amplifier in the first semiconductor component, a second subsequent-stage amplifier in the third semiconductor component, and a second passive component connected between the second preceding-stage amplifier and the second subsequent-stage amplifier,
wherein the first semiconductor component is disposed between the first passive component and the second passive component in a plan view of the module laminate.

2. The radio frequency module according to claim 1,
wherein the first passive component is disposed between the first semiconductor component and the second semiconductor component in plan view of the module laminate.

3. The radio frequency module according to claim 2,
wherein the second passive component is disposed between the first semiconductor component and the third semiconductor component in the plan view of the module laminate.

4. The radio frequency module according to claim 1, further comprising:
a first transmit filter connected to the first power amplifier circuit, the first transmit filter having a passband that includes a transmission band of a first band included in a first band group; and
a second transmit filter connected to the second power amplifier circuit, the second transmit filter having a passband that includes a transmission band of a second band included in a second band group higher than the first band group,
wherein harmonic bands of the transmission band of the first band at least partially overlap with the transmission band of the second band.

5. The radio frequency module according to claim 1, further comprising
a third power amplifier circuit,
wherein the third power amplifier circuit includes
a third preceding-stage amplifier,
a third subsequent-stage amplifiers, and
a third passive component connected between the third preceding-stage amplifier and the third subsequent-stage amplifiers,
wherein the first semiconductor component further includes the third preceding-stage amplifier,
wherein the third subsequent-stage amplifiers is included in a fourth semiconductor component disposed at the module laminate, and
wherein the first semiconductor component is disposed between the first passive component and the third passive component in the plan view of the module laminate.

6. The radio frequency module according to claim 5, further comprising:
a first transmit filter connected to the first power amplifier circuit, the first transmit filter having a passband that includes a transmission band of a first band included in a first band group;
a second transmit filter connected to the second power amplifier circuit, the second transmit filter having a passband that includes a transmission band of a second band included in a second band group higher than the first band group; and
a third transmit filter connected to the third power amplifier circuit, the third transmit filter having a passband that includes a transmission band of a third band included in a third band group higher than the second band group,
wherein harmonic bands of the transmission band of the first band at least partially overlap with the transmission band of the third band.

7. The radio frequency module according to claim 5,
wherein the third passive component is disposed between the first semiconductor component and the fourth semiconductor component in the plan view of the module laminate.

8. The radio frequency module according to claim 1, further comprising:
a first transmit filter having a passband that includes a transmission band of a first band included in a first band group;
a fourth transmit filter having a passband that includes a transmission band of a fourth band included in the first band group; and
a first switch circuit including
a first common terminal that is connected to the first power amplifier circuit,
a first selection terminal that is connected to the first transmit filter, and
a second selection terminal that is connected to the fourth transmit filter,
wherein the first band is a 5th Generation New Radio (5G NR) band or a 4th Generation Long Term Evolution (4G LTE) band, and
wherein the fourth band is a 2nd Generation Global System for Mobile communications (2G GSM) band.

9. The radio frequency module according to claim 1, further comprising:
a second transmit filter having a passband that includes a transmission band of a second band included in a second band group;
a fifth transmit filter having a passband that includes a transmission band of a fifth band included in the second band group; and
a second switch circuit including
a second common terminal that is connected to the second power amplifier circuit,
a third selection terminal that is connected to the second transmit filter, and
a fourth selection terminal that is connected to the fifth transmit filter,
wherein the second band is a 5G NR band or a 4G LTE band, and
wherein the fifth band is a 2G GSM band.

10. The radio frequency module according to claim 1, wherein
the first and second passive components are each a balun,
the first power amplifier includes another first subsequent-stage amplifier,
the second power amplifier includes another second subsequent-stage amplifier,
the first power amplifier circuit further includes a fourth balun that is connected to an output terminal of each of the two first subsequent-stage amplifiers,
wherein the second power amplifier circuit further includes a fifth balun that is connected to an output terminal of each of the two second subsequent-stage amplifiers, and
wherein the first semiconductor component and the third semiconductor component are disposed between the fourth balun and the fifth balun in the plan view of the module laminate.

11. The radio frequency module according to claim 5, wherein
the first and second passive components are each a balun,
the first power amplifier includes another first subsequent-stage amplifier,
the second power amplifier includes another second subsequent-stage amplifier,
the first power amplifier circuit further includes a fourth balun that is connected to an output terminal of each of the two first subsequent-stage amplifiers,
the third power amplifier circuit further includes a sixth balun that is connected to an output terminal of each of the two third subsequent-stage amplifiers, and
the first semiconductor component and the fourth semiconductor component are disposed between the fourth balun and the sixth balun in the plan view of the module laminate.

12. The radio frequency module according to claim 1, wherein
the first and second passive components are each a balun,
the first power amplifier includes another first subsequent-stage amplifier,
the second power amplifier includes another second subsequent-stage amplifier,
the first power amplifier circuit further includes a fourth balun that is connected to an output terminal of each of the two first subsequent-stage amplifiers,
wherein the second semiconductor component has a rectangular shape in the plan view of the module laminate,
wherein the first balun is disposed adjacent to a first edge of the second semiconductor component in the plan view of the module laminate, and
wherein the fourth balun is disposed adjacent to a second edge of the second semiconductor component in the plan view of the module laminate, the second edge being adjacent to the first edge.

13. The radio frequency module according to claim 1, wherein
the first and second passive components are each a balun,
the first power amplifier includes another first subsequent-stage amplifier,
the second power amplifier includes another second subsequent-stage amplifier,
the first power amplifier circuit further includes a fourth balun that is connected to an output terminal of each of the two first subsequent-stage amplifiers,
wherein the second semiconductor component has a rectangular shape in the plan view of the module laminate,
wherein the first balun is disposed adjacent to a first edge of the second semiconductor component in the plan view of the module laminate, and
wherein the fourth balun is disposed adjacent to a third edge of the second semiconductor component in the plan view of the module laminate, the third edge being opposite to the first edge.

14. The radio frequency module according to claim 1,
wherein a first semiconductor material of the first semiconductor is different from a second semiconductor material of the second semiconductor component and from a third semiconductor material of the third semiconductor component.

15. The radio frequency module according to claim 14,
wherein the first semiconductor material is silicon (Si), and
wherein the second and third semiconductor materials is gallium arsenide (GaAs).

16. The radio frequency module according to claim 1, further comprising
a metal shield disposed between the first passive component and the second passive component in the plan view of the module laminate.

17. The radio frequency module according to claim 16,
wherein the metal shield includes a plurality of bonding wires disposed on the first semiconductor component.

18. The radio frequency module according to claim 16,
wherein the metal shield includes a metal wall disposed on the first semiconductor component.

19. The radio frequency module according to claim 1,
wherein the second semiconductor component is disposed at one of a first major face of the module laminate and a second major face of the module laminate, the second major face being opposite the first major face, and
wherein the third semiconductor component is disposed at another one of the first major face and the second major face of the module laminate.

20. The radio frequency module according to claim 1, wherein the first and second passive components are each an inductor.
